(19) United States
(12) Patent Application Publication
(10) Pub. No.: US 2024/0274469 A1
(43) Pub. Date: Aug. 15, 2024

(54) SEMICONDUCTOR STRUCTURE WITH DEVICES HAVING DIFFERENT EFFECTIVE CHANNELS AND METHOD FOR MANUFACTURING THE SAME

(71) Applicant: TAIWAN SEMICONDUCTOR MANUFACTURING COMPANY, LTD., Hsinchu (TW)

(72) Inventors: Ta-Chun LIN, Hsinchu (TW); Jhon Jhy LIAW, Hsinchu (TW)

(73) Assignee: TAIWAN SEMICONDUCTOR MANUFACTURING COMPANY, LTD., Hsinchu (TW)

(21) Appl. No.: 18/168,884

(22) Filed: Feb. 14, 2023

(51) Int. Cl. H01L 21/8234; H01L 27/088

(52) U.S. Cl. CPC H01L 21/823412; H01L 21/823418; H01L 21/823456; H01L 27/088

(57) ABSTRACT

A semiconductor structure includes an elongated fin, and a first device and a second device disposed on the elongated fin. Each of the first and second devices includes two source/drain portions, a channel portion including effective channel layer(s), and a gate structure disposed around the effective channel layer(s). A number of the effective channel layer(s) in the second device is greater than a number of the effective channel layer(s) in the first device. Methods for manufacturing the semiconductor structure are also disclosed.

### BACKGROUND

Transistors are key active components in modern integrated circuits (ICs). With rapid development of semiconductor technology, critical dimension (CD) of transistors keeps shrinking and various three-dimensional (3D) transistor structures are springing up, making it possible to integrate a large number of transistors per unit area. In addition, transistors in an IC may not be exactly the same, and may have difference in configuration and/or specifications (e.g., threshold voltage, saturation current, off current, etc.), so that the transistors can be integrated together to form different operating units (e.g., memories, inverters, logic gates, flash, etc.) with different functions. Till date, advanced node 3D ICs including different operating units integrated therein are under continuous development.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 99 illustrate schematic views of intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

Although critical dimension (CD) of transistors continues to shrink and various three-dimensional (3D) transistor structures (e.g., a gate-all-around (GAA) structure, a forksheet structure, etc.) are springing up for manufacturing integrated circuit (IC) with a high integration density, there is still a requirement to provide customers with transistors having a much wider range of specifications (e.g., extreme-low power consumption, extreme-high-speed computing, etc.), which will facilitate design of integrated circuits with excellent performance. The present disclosure is directed to a semiconductor structure including a plurality of devices which are adjacent to each other and which have various numbers of channels and/or various channel widths, as described in the following. The devices in the semiconductor structure may be independently configured as nanosheet GAA field-effect transistors (GAA FETs), nanowire GAA FETs, complementary FETs (CFET), fork-sheet FETs, or other suitable configurations. The devices in the semiconductor structure may be integrated to function as memory cells, inverters, logic gates (e.g., NOR gates and NAND gates), or for other suitable applications.

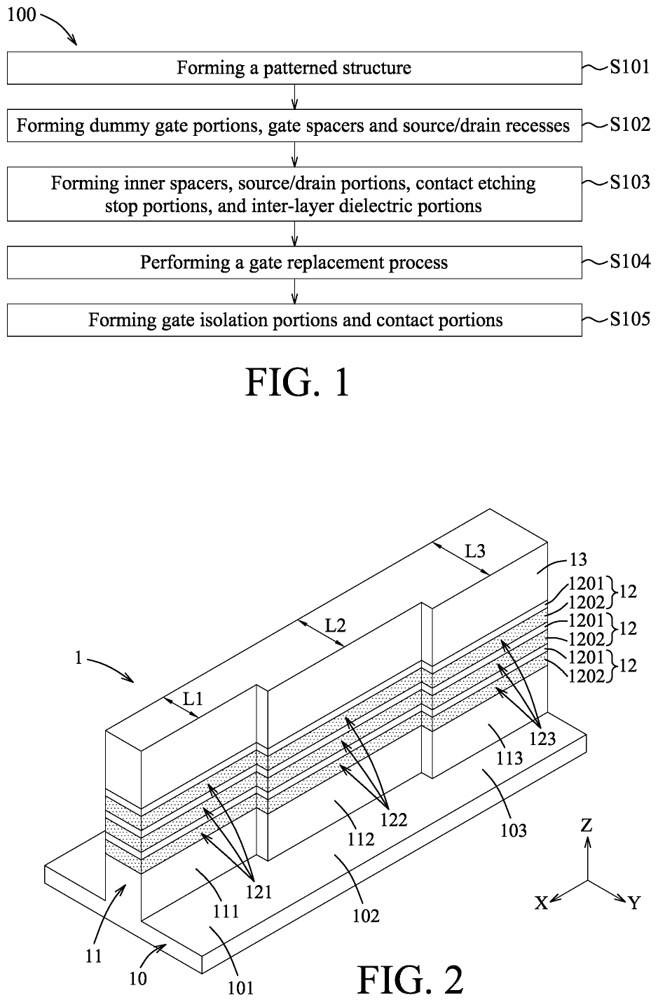

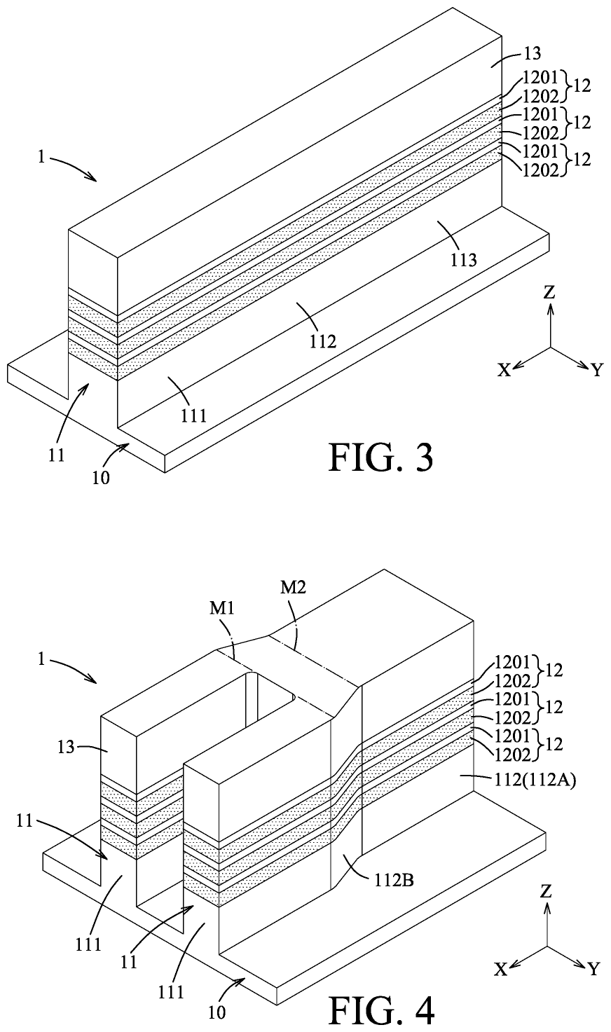

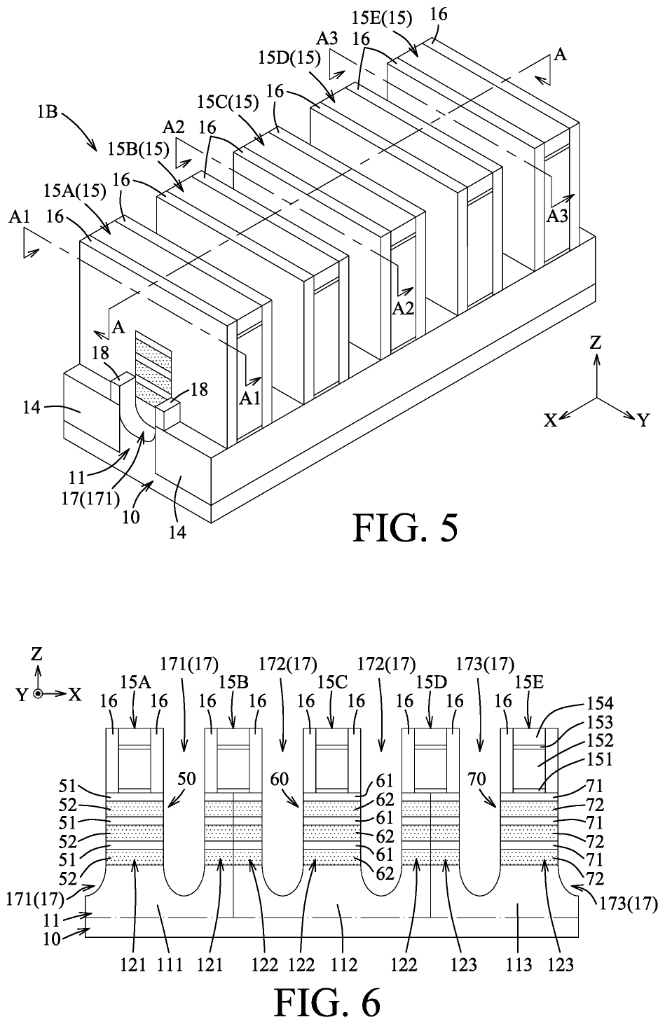

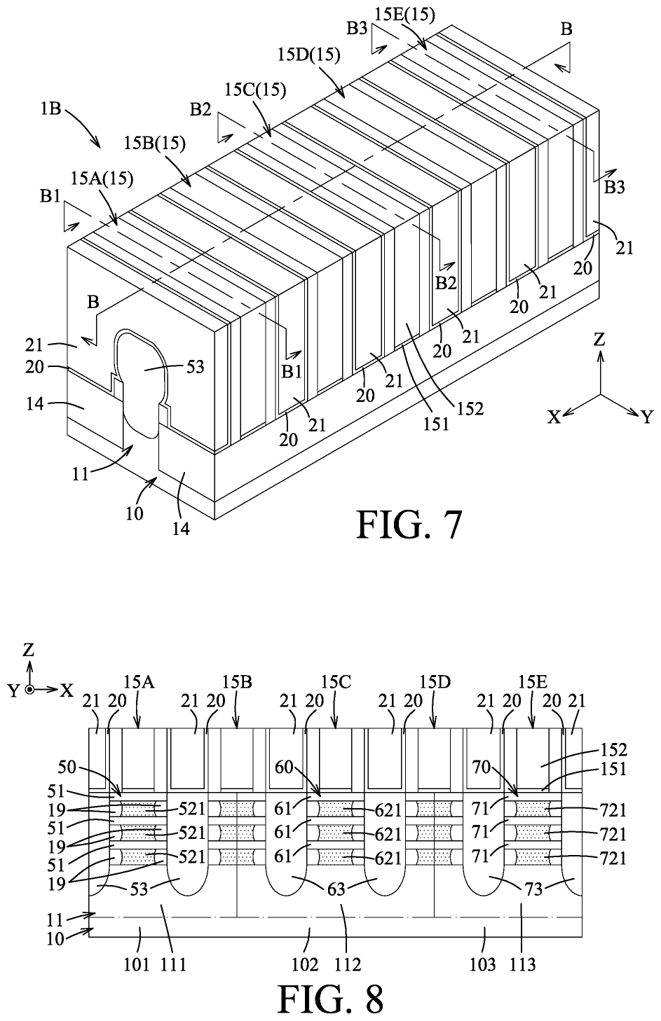

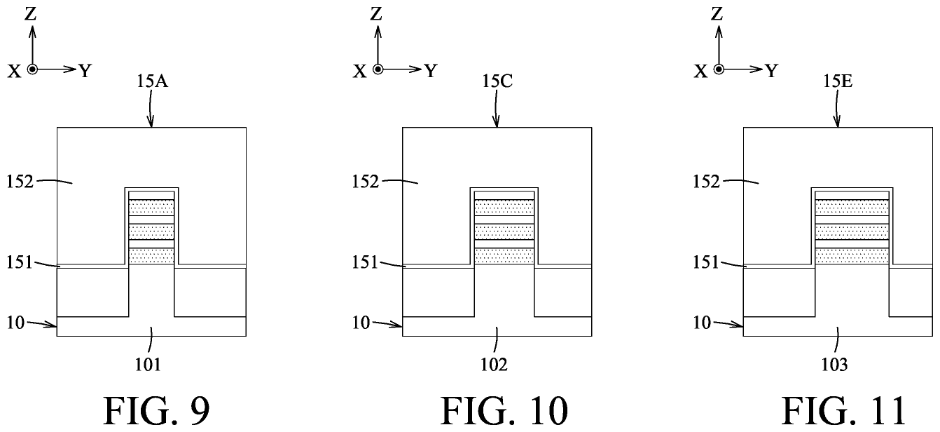

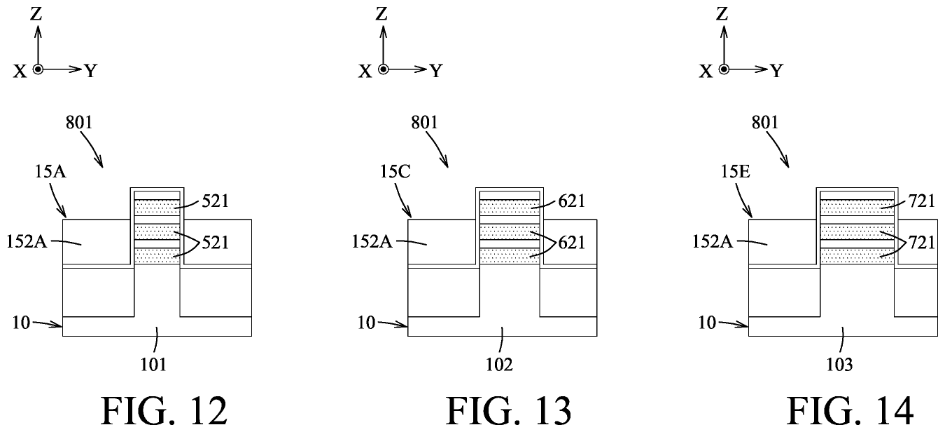

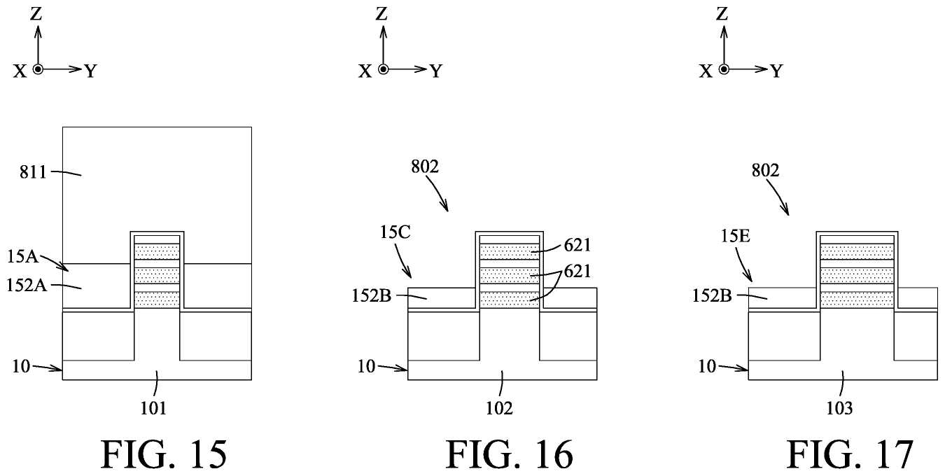

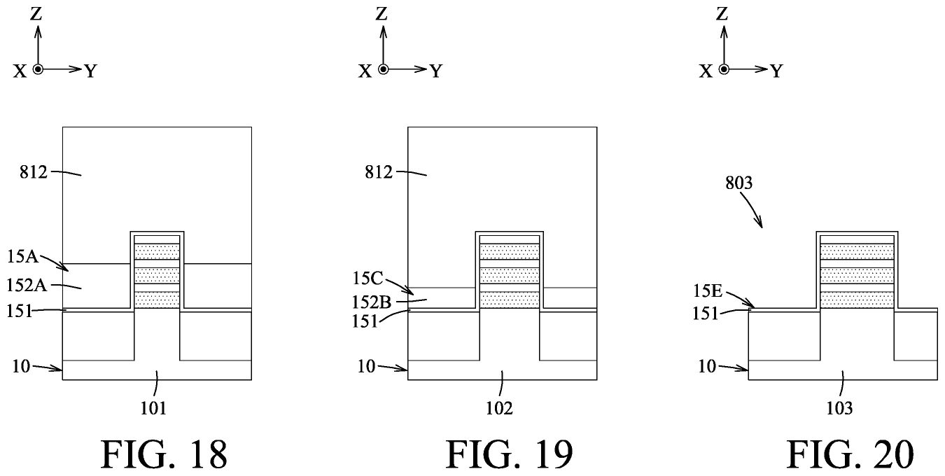

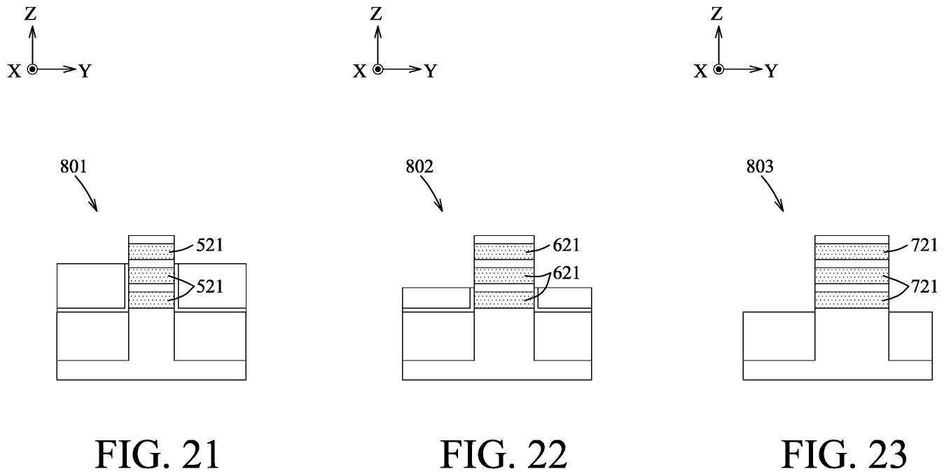

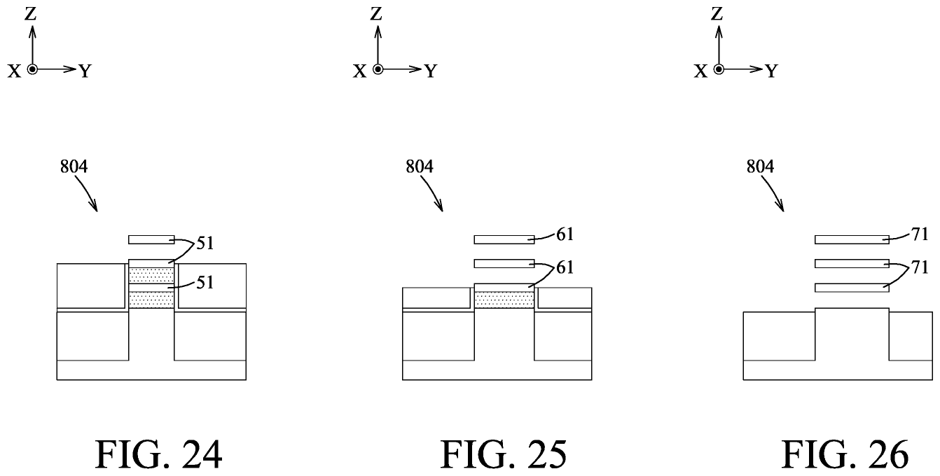

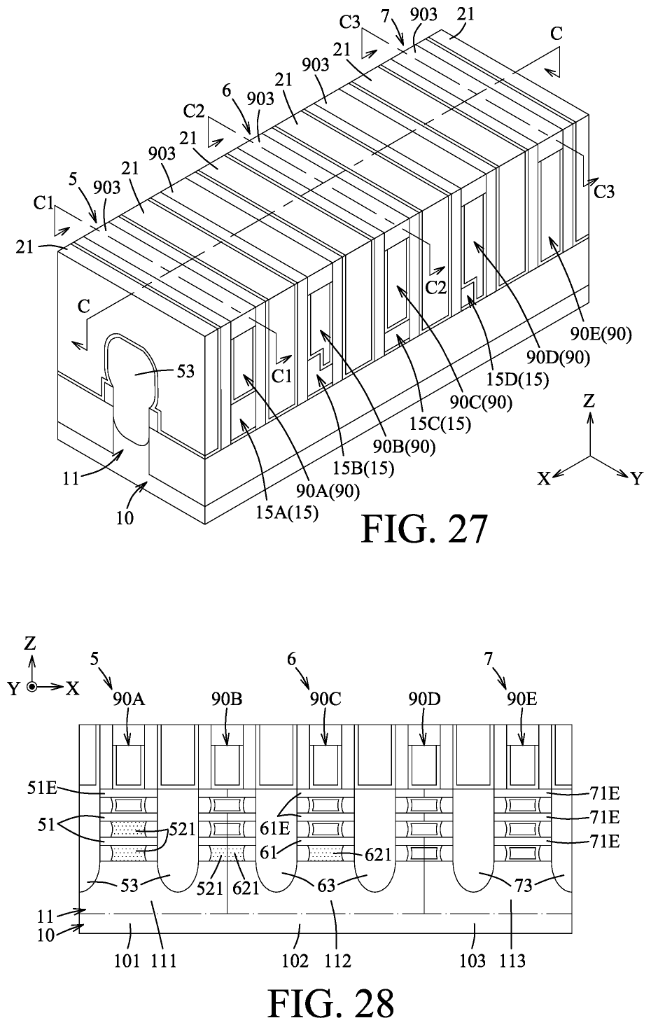

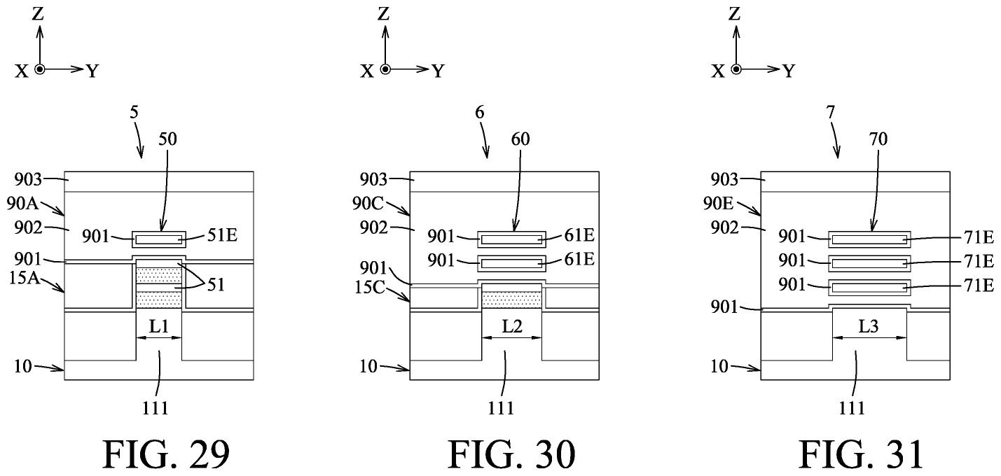

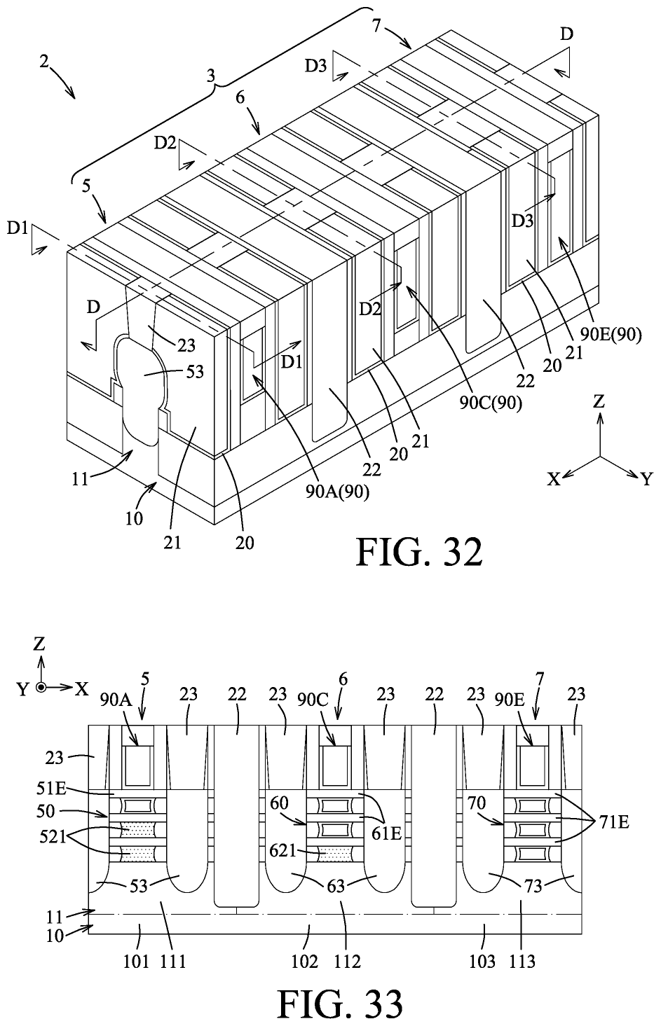

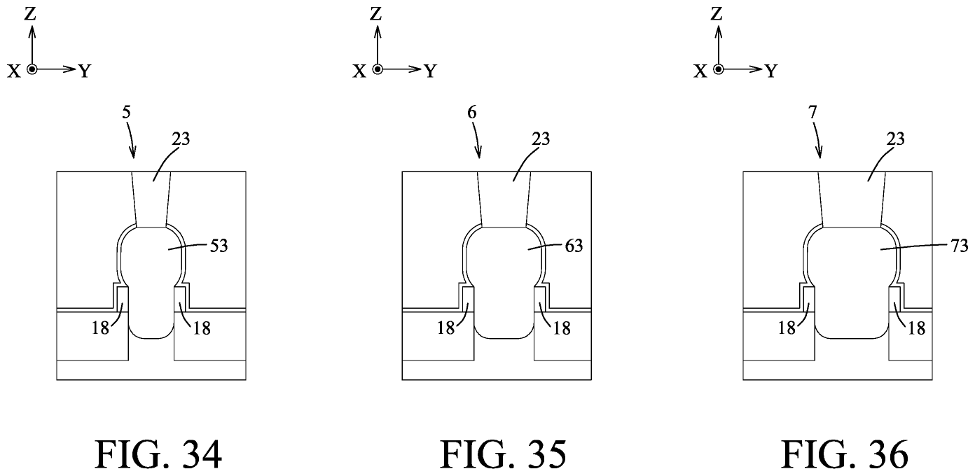

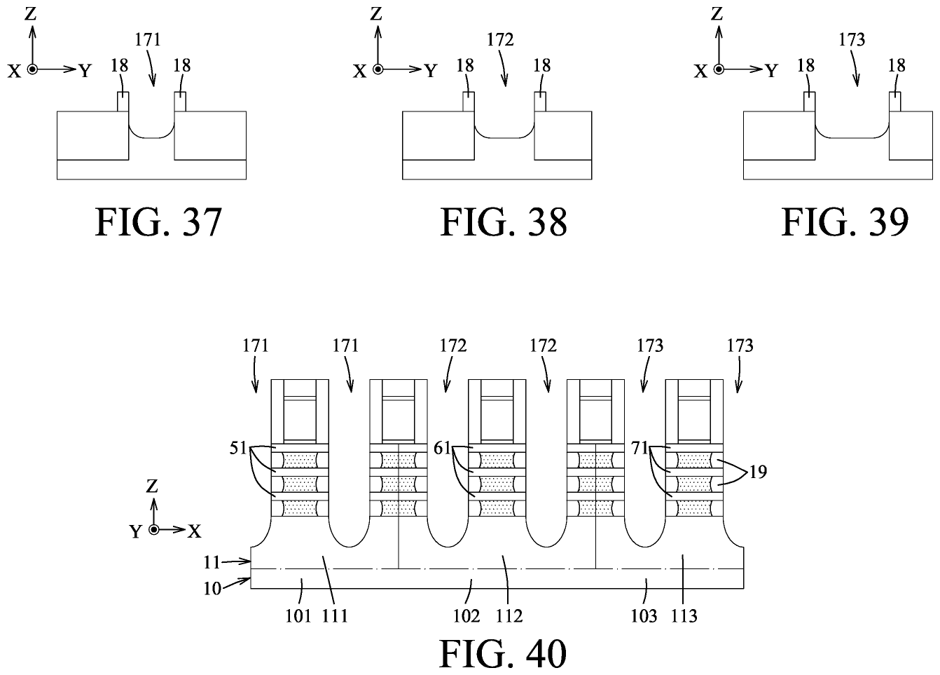

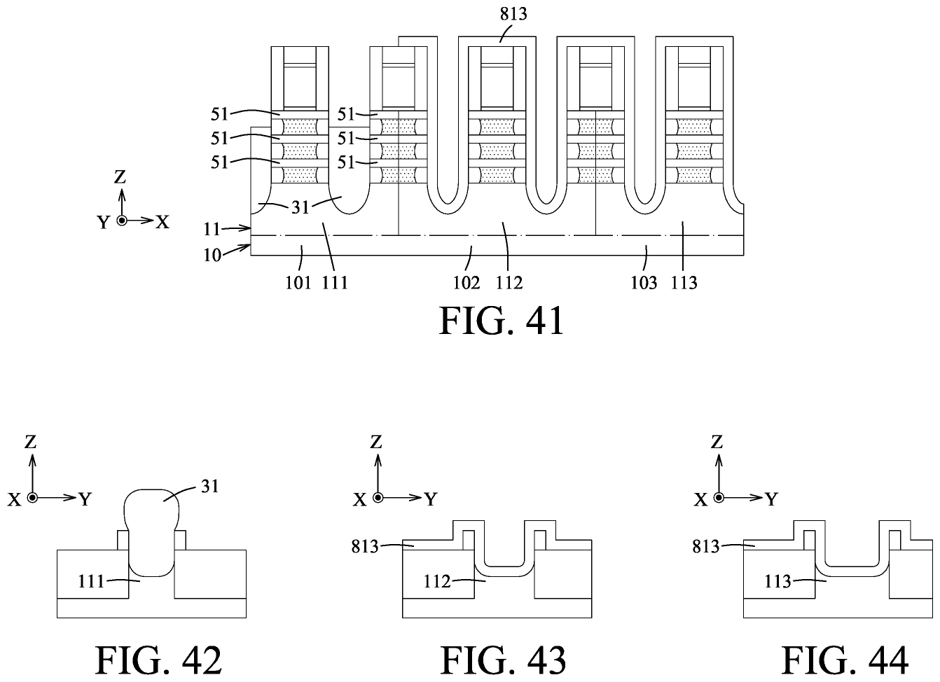

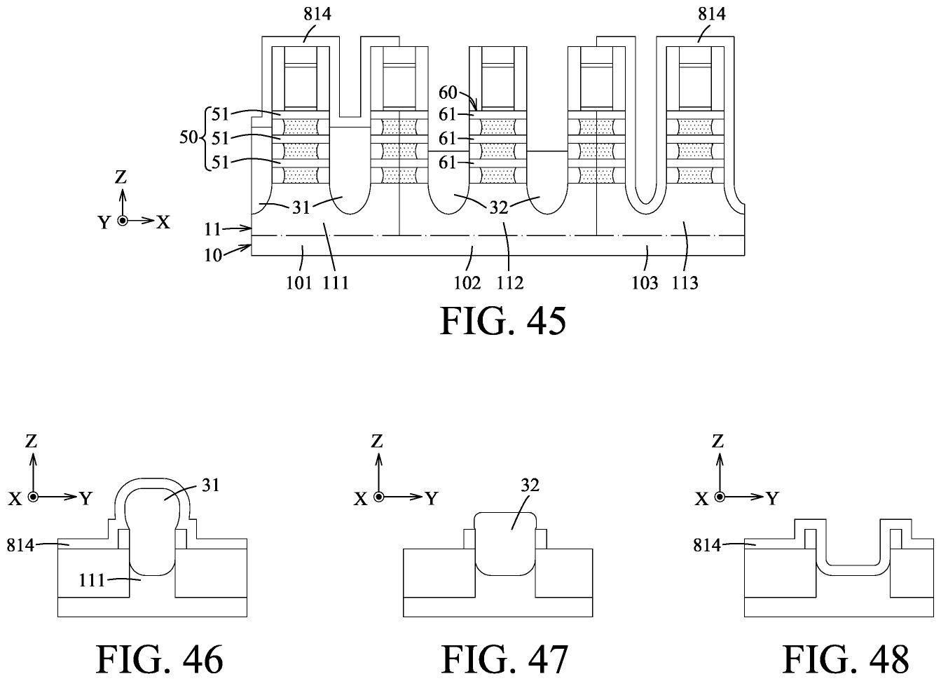

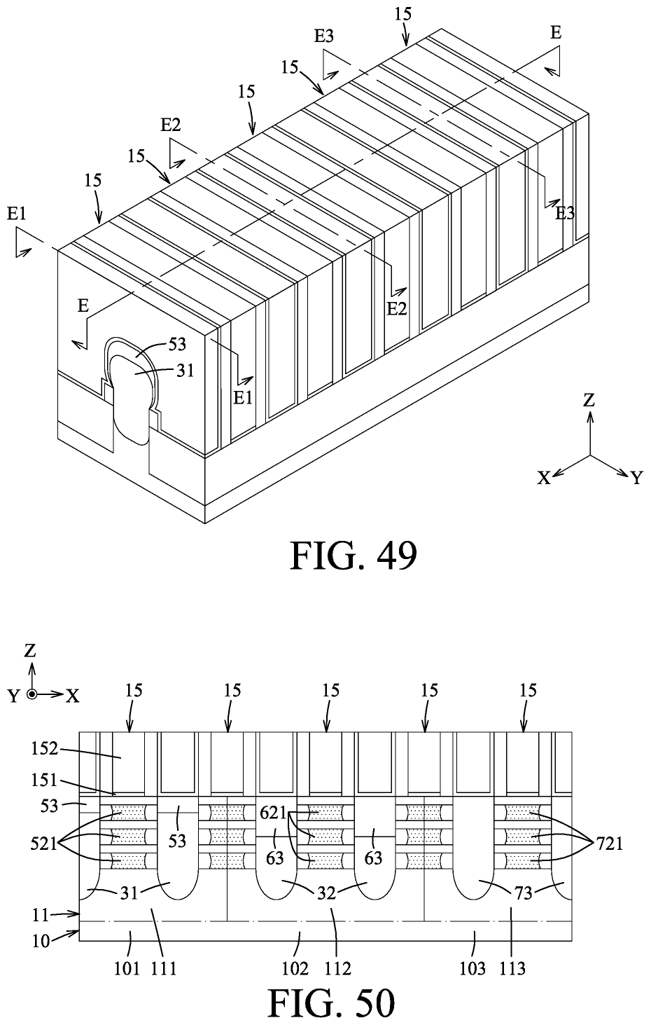

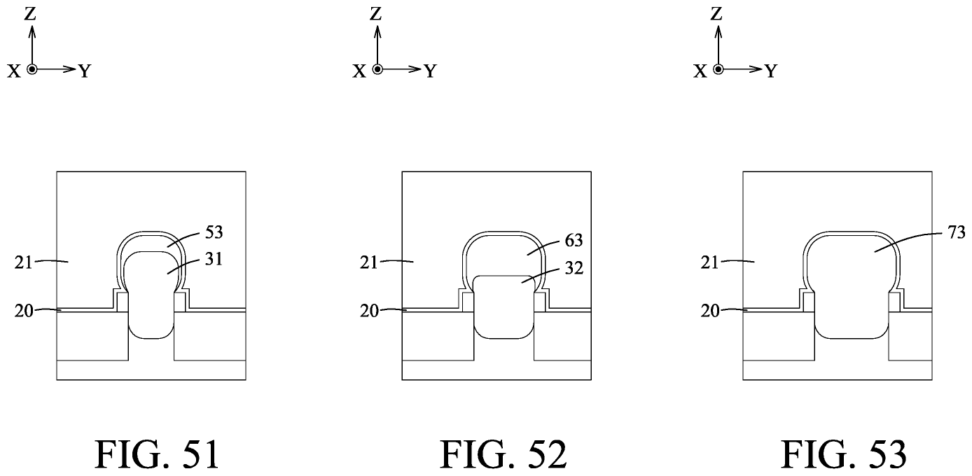

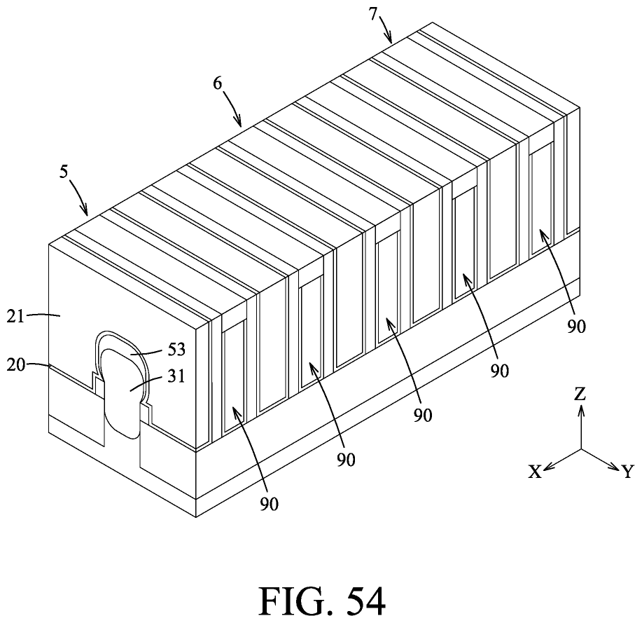

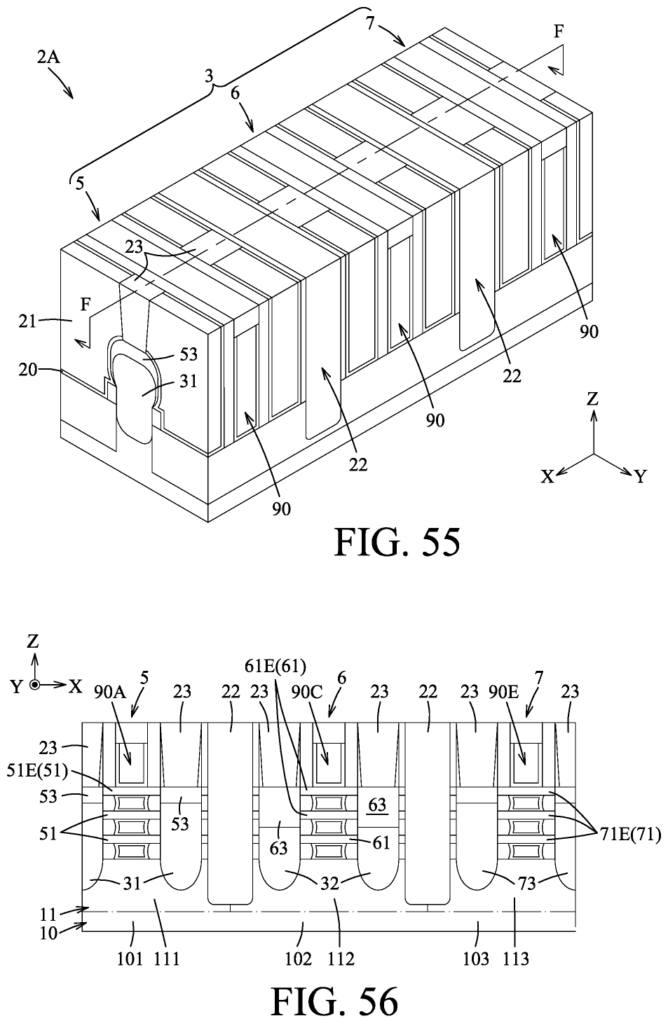

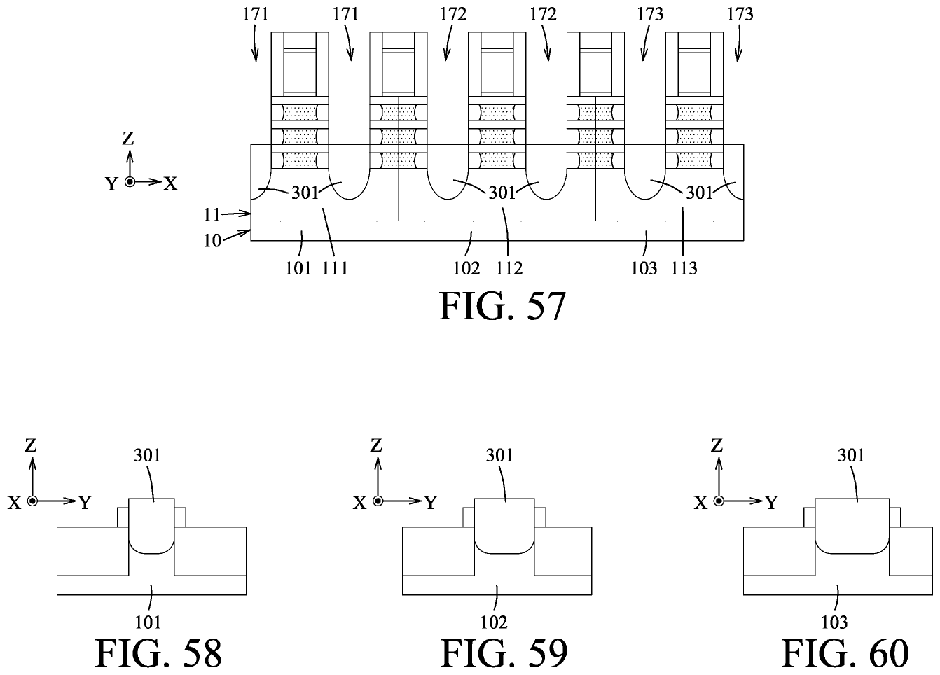

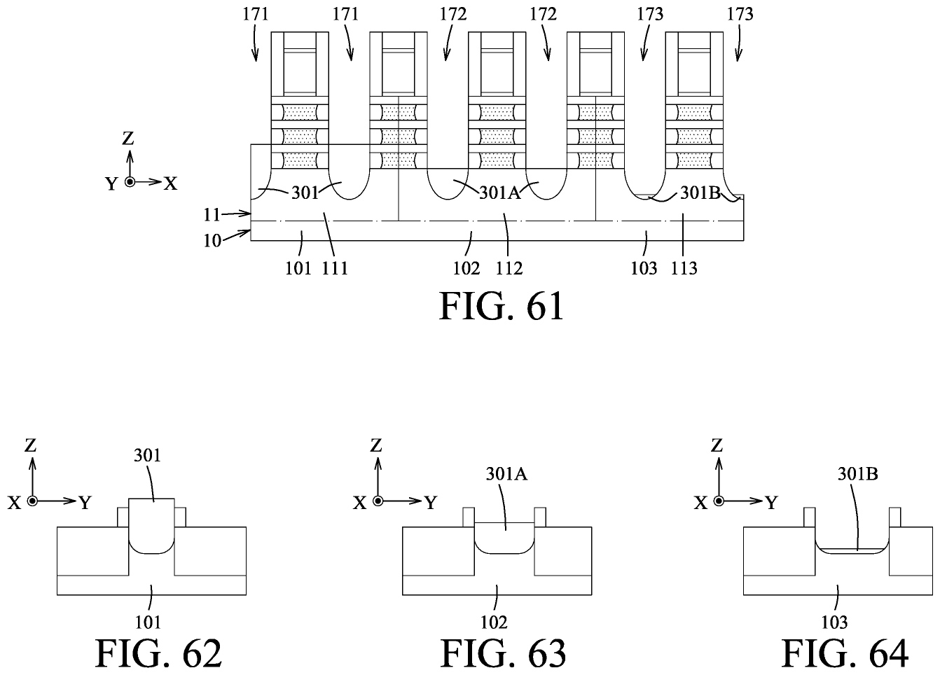

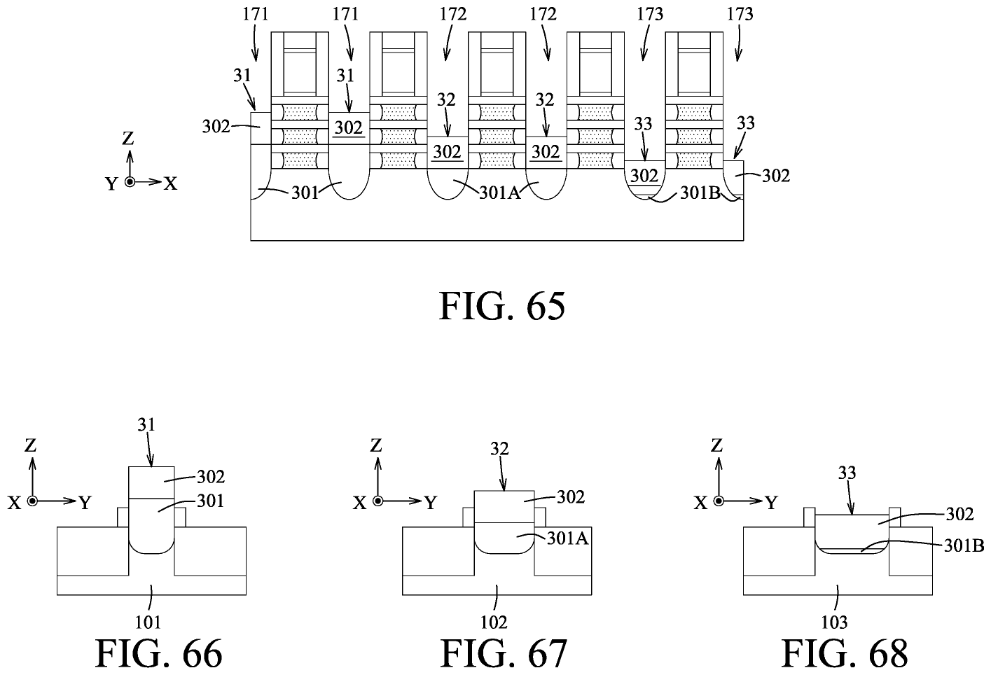

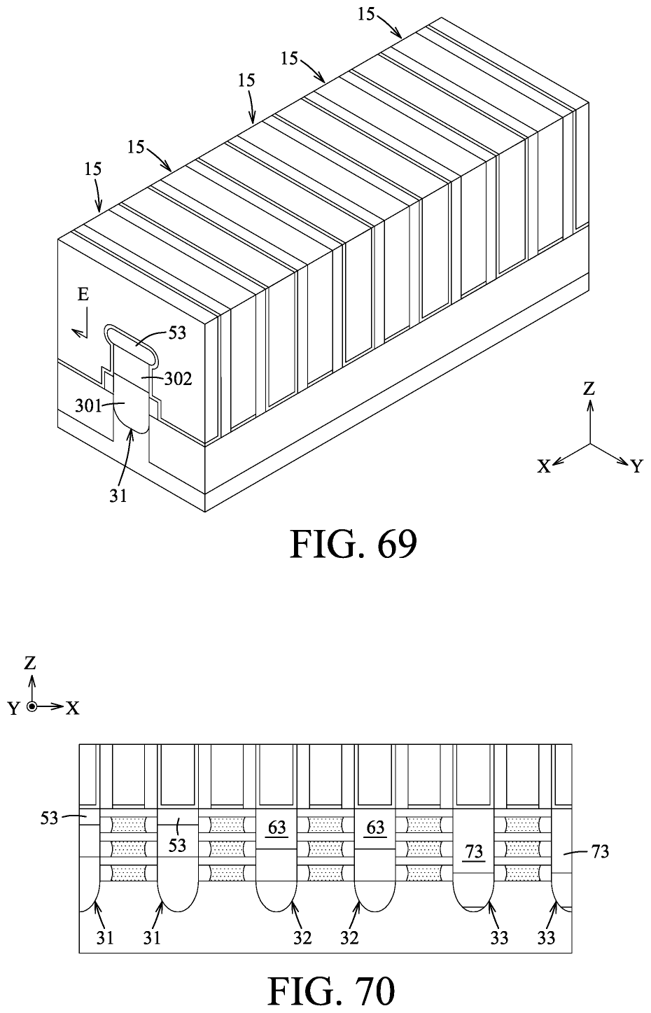

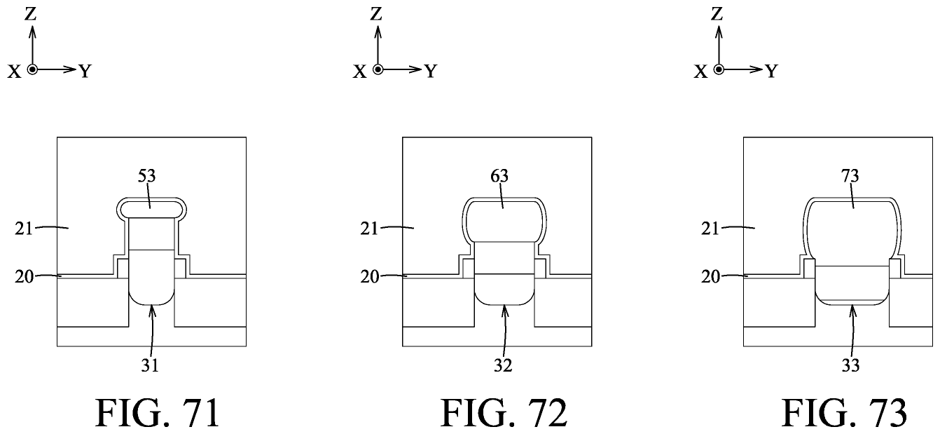

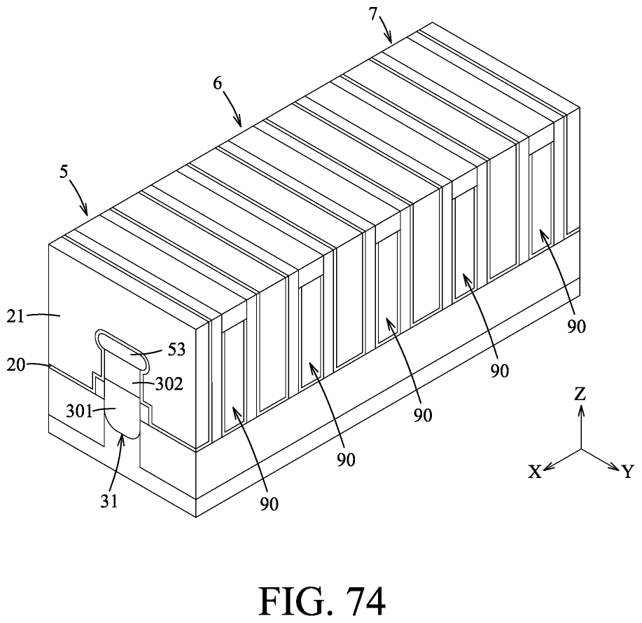

FIG. 1 is flow diagram illustrating a method 100 for manufacturing a semiconductor structure including at least one device assembly which includes a plurality of devices (for example, a semiconductor structure 2 shown in FIG. 32 which includes at least one device assembly 3) in accordance with some embodiments. FIGS. 2 to 36 illustrate schematic views of intermediate stages of the method 100 in accordance with some embodiments. Some repeating structures are omitted in FIGS. 2 to 36 for the sake of brevity.

Referring to FIG. 1 and the examples illustrated in FIGS. 2, 3 and 4, the method 100 begins at step S101, where a patterned structure 1 is formed. FIG. 2 is a perspective schematic view of the patterned structure 1 in accordance with some embodiment. FIGS. 3 and 4 are perspective schematic views of first and second variants of the patterned structure 1, respectively, in accordance with some other embodiments.

The patterned structure 1 includes a semiconductor substrate 10, at least one elongated fin 11 disposed on the semiconductor substrate 10, a plurality of stack units 12 disposed on the at least one elongated fin 11, and a hard mask portion 13 disposed on an uppermost one of the stack units 12.

In some embodiments, the semiconductor substrate 10 includes a plurality of regions for different types of devices to be formed thereon. When some of the devices each having the same number of effective channel layers, they are referred to as the same type of the devices and may be formed on the same region of the semiconductor substrate 10.

For example, as shown in FIG. 2, the semiconductor substrate 10 includes a first region 101 which are designed to form at least one first device 5 (see FIG. 32) thereon, a second region 102 which are designed to form at least one second device 6 thereon, and a third region 103 which are designed to form at least one third device 7 thereon. As shown in FIG. 32, a single one of the first device 5, a single one of the second device 6, and a single one of the third device 7 are formed as an example.

As shown in FIGS. 2 and 3, the elongated fin 11 has a first fin portion 111, a second fin portion 112 and a third fin portion 113 respectively disposed on the first, second and third regions 101, 102, 103. The first, second and third fin portions 111, 112, 113 are formed continuously and displaced from each other in an X direction.

When viewing the patterned structure 1 from a Z direction (transverse to the X direction), each of the stack units 12 has a shape substantially the same as that of the elongated fin 11. Each of the stack units 12 includes a first stack 121, a second stack 122 and a third stack 123 which are respectively disposed on the first, second and third fin portions 111, 112, 113. Each of the stacks 121, 122, 123 includes a channel film 1201 which is made of a first semiconductor material and a sacrificial film 1202 which is made of a second semiconductor material that is different from the first semiconductor material. The channel film 1201 and the sacrificial film 1202 of each of the stacks 121, 122, 123 are disposed distal from and proximate to the semiconductor substrate 10, respectively. The channel films 1201 of the first, second and third stacks 121, 122, 123 respectively have a first channel width, a second channel width and a third channel width in a Y direction which are substantially equal to a first fin width, a second fin width and a third fin width of the first, second and third fin portions 111, 112, 113 in the Y direction, respectively. Each of the first channel width and the first film width is substantially the same as a length L1 in FIG. 2, each of the second channel width and the second film width is substantially the same as a length L2 in FIG. 2, and each of the third channel width and the third film width is substantially the same as a length L3 in FIG. 2. The third fin width is greater than the second fin width, and the second fin width is greater than the first fin width. That is to say, the third channel width is greater than the second channel width, and the second channel width is greater than the first channel width. In some embodiments, a ratio of the length L2 to the length L1 (i.e., L2/L1) may range from about 1.1 to about 3. In some embodiments, a ratio of the length L3 to the length L2 (i.e.,L3/L2) may range from about 1.1 to about 3. The first, second and third devices 5, 6, 7 shown in FIGS. 32 and 33 will be respectively formed on the first, second and third fin portions 111, 112, 113 in subsequent processes. The channel widths of the channel films 1201 of the stacks 121, 122, 123, which are adjustable and determined in step S101, will respectively affect channel widths in the Y direction of channel layers 51, 61, 71 (see FIGS. 29 to 31) to be subsequently formed. Although the elongated fin 11 shown in FIG. 2 is divided into three of the fin portions 111, 112, 113 having fin widths different from one another, the number of the fin portions and a configuration (i.e., a shape viewed from the Z direction) of the elongated fin 11 may vary according to application requirements. In some embodiments, the X, Y and Z directions are perpendicular to one another.

In some embodiments, the semiconductor substrate 10 may be made of elemental semiconductor materials, such as crystalline silicon (Si), diamond, or germanium (Ge); compound semiconductor materials, such as gallium nitride (GaN), silicon carbide (SiC), gallium arsenide (GaAs), indium arsenide (InAs), or indium phosphide (InP); or alloy semiconductor materials, such as silicon germanium (SiGe), silicon germanium carbide, gallium arsenic phosphide (GaAsP), or gallium indium phosphide (GaInP). The material for forming the semiconductor substrate 10 may be doped with p-type impurities or n-type impurities, or undoped. In addition, the semiconductor substrate 10 may be a bulk silicon substrate, a silicon-on-insulator (SOI) substrate, or a germanium-on-insulator (GOI) substrate. Other suitable materials and/or configurations for the semiconductor substrate 10 are within the contemplated scope of the present disclosure.

Materials suitable for forming the at least one elongated fin 11 are substantially the same as those for forming the semiconductor substrate 10. The at least one elongated fin 11 may be made of a material the same as or different from that of the semiconductor substrate 10.

In some embodiments, the first and second semiconductor materials suitable for forming the channel film 1201 and the sacrificial film 1202 in each of the stacks 121, 122, 123 are similar to those for forming the semiconductor substrate 10. The second semiconductor material is different from the first semiconductor material, so that the sacrificial film 1202 can be selectively removed with respect to the channel film 1201 during subsequent processes. In some embodiments, the channel film 1201 is made of Si, and the sacrificial film 1202 is made of SiGe. Other suitable materials for the channel film 1201 and the sacrificial film 1202 are within the contemplated scope of the present disclosure. It is noted that the number of the stack units 12 shown in FIGS. 2 to 4 is three, but is not limited thereto. In practical, the number of the stack units 12 may vary according to application requirements, and may affect the number of types of devices that can be designed, which will be described in the following paragraph. Although the thickness of the sacrificial film 1202 is shown to be greater than that of the channel film 1201, the thickness of the sacrificial film 1202 may be equal to or smaller than that of the channel film 1201 according to practical requirements.

In some embodiments, the hard mask portion 13 may include a low dielectric constant (low-k) material (such as silicon oxide, silicon nitride, silicon oxynitride, silicon carbonitride, silicon oxycarbide, silicon oxycarbonitride, silicon carbide, and so on), a high dielectric constant (high-k) material (such as hafnium oxide, zirconium oxide, zirconium aluminum oxide, hafnium aluminum oxide, hafnium silicon oxide, aluminum oxide, and so on), or a combination thereof. Other suitable materials for the hard mask portion 13 are within the contemplated scope of the present disclosure.

In some embodiments, the patterned structure 1 may be formed by patterning a starting substrate (not shown) and a stack assembly (not shown) formed on the starting substrate to form the elongated fin 11 on the semiconductor substrate 10 and the stack units 12 on the elongated fin 11. To be specific, the starting substrate is patterned into the semiconductor substrate 10 and the elongated fin 11 including the fin portions 111, 112, 113, and the stack assembly is patterned into the stack units 12, each of which includes the stacks 121, 122, 123 respectively disposed on the fin portions 111, 112, 113.

FIG. 3 is a view similar to that of FIG. 2 but illustrating the elongated fin 11 including the fins portions 111, 112, 113 having the same fin width in accordance with some other embodiments. Likewise, each of the stack units 12 has a shape viewed from the Z direction the same with that of the elongated fin 11. FIG. 4 is a view similar to that of FIG. 2 but illustrating two of the elongated fins 11 in accordance with some other embodiments. Each of the elongated fins 11 shown in FIG. 4 includes the first and second fin portions 111, 112. The first fin portions 111 of the elongated fins 11 are spaced apart from each other in the Y direction, and the second fin portions 112 of the elongated fins 11 are merged together to form a merged fin portion. The merged fin portion includes a main part 112A and a connected part 112B which connects the main part 112 to the first fin portions 111 of the elongated fins 11. The main part 112A has a merged fin width.

In some embodiments, the first fin widths of the first fin portions 111 are substantial the same, and the merged fin width is greater than each of the first fin widths. Likewise, when viewing the patterned structure 1 from the Z direction, each of the stack units 12 has a shape substantially the same with a combined shape of the two elongated fins 11.

Since the semiconductor structure made by the method 100 may have a plurality of layout designs based on application requirements, in the following steps, the structure shown in FIG. 2 is to be further illustrated, and the structures shown in FIGS. 3 and 4 will not be further illustrated for the sake of brevity.

Referring to FIG. 1 and the examples illustrated in FIGS. 5 and 6, the method 100 proceeds to step S102, where a plurality of insulating portions 14 (two of which are shown), a plurality of dummy gate portions 15, a plurality pairs of gate spacer 16 are formed, and the stack units 12 shown in FIG. 2 are patterned to have a plurality pairs of source/drain recesses 17. FIG. 5 is a view similar to that of FIG. 2, but illustrating the structure after step S102. FIG. 6 is a schematic cross-sectional view taken along line A-A of FIG. 5.

In some embodiments, step S102 may include sub-steps S1021 to S1023.

In sub-step S1021, the two insulating portions 14 are formed at two opposite sides of the elongated fin 11 which are opposite to each other in the Y direction. In some embodiments, each of the insulating portions 14 may be a portion of a shallow trench isolation (STI), a deep trench isolation (DTI), or other suitable structures. The insulating portions 14 may include a suitable low-k material (such as the examples described in the preceding paragraph). Other suitable materials and/or configurations for the insulating portions 14 are within the contemplated scope of the present disclosure. In some embodiments, the insulating portions 14 may be formed by (i) forming an insulating layer (not shown) to cover the structure shown in FIG. 2, followed by a planarization process, for example, but not limited to, chemical mechanical polishing (CMP), to expose the hard mask portion 13 such that insulating regions (not shown) are formed at two opposite sides of each of the stack units 12, which are opposite to each other in the Y direction, and (ii) recessing the insulating regions to form the insulating portions 14 by dry etching to expose the stack units 12. It is noted that the hard mask portion 13 (see FIG. 2) may be consumed and removed after sub-step S1021. Other suitable processes for forming the insulating portions 14 are within the contemplated scope of the present disclosure.

In sub-step S1022, the dummy gate portions 15 are formed over the structure obtained after sub-step S1021, and are each elongated in the Y direction. Two adjacent ones of the dummy gate portions 15 are spaced apart from each other in the X direction.

For the purposes of simplicity and clarity, the number of the dummy gate portions 15 shown in FIGS. 5 and 6 is five. For better illustration, as shown in FIGS. 5 and 6, (i) the dummy gate portion disposed over the first stacks 121 of the stack units 12 (see also FIG. 2) is denoted by 15A, (ii) the dummy gate portion disposed to over a juncture between the stacks 121, 122 of the stack units 12 is denoted by 15B, (iii) the dummy gate portion disposed over the second stacks 122 of the stack units 12 is denoted by 15C, (iv) the dummy gate portion disposed to over a juncture between the stacks 122, 123 of the stack units 12 is denoted by 15D, and (v) the dummy gate portion disposed over the third stacks 123 of the stack units 12 is denoted by 15E. In practical, the number of the dummy gate portions 15 are determined according to application requirements.

Each of the dummy gate portions 15 has a poly width in the X direction. The poly width of each of the dummy gate portions 15 will affect a gate length in the X direction of a corresponding one of gate structures 90 (see FIG. 27) to be subsequently formed, and is positively correlated with a channel length in the X direction of the channel layers 51, 61, 71 (see FIG. 28).

In some embodiments, each of the dummy gate portions 15 may include, in a direction away from the semiconductor substrate 10, a dummy gate dielectric film 151, a dummy gate electrode 152, a polish stop layer 153, and a hard mask film 154. In some embodiments, each of the hard mask film 154 and the polish stop layer 153 may independently include silicon nitride, silicon oxide, silicon oxynitride, or combinations thereof; the dummy gate electrode 152 may include polycrystalline silicon, single crystalline silicon, amorphous silicon, or combinations thereof; and the dummy gate dielectric film 151 may include silicon oxide, silicon nitride, silicon oxynitride, a suitable high-k material (such as the examples described in the preceding paragraph), or combinations thereof. In some embodiments, the dummy gate portions 15 may be formed by (i) sequentially depositing two layers of materials for forming the dummy gate dielectric film 151 and the dummy gate electrode 152 over the structure obtained after sub-step S1021 using physical vapor deposition (PVD), chemical vapor deposition (CVD), atomic layer deposition (ALD), or other suitable processes, (ii) performing a planarization process using, for example, CMP to form a planar surface, (iii) sequentially depositing another two layers of materials for forming the polish stop layer 153 and the hard mask film 154 using PVD, CVD, ALD or other suitable processes, and (iv) patterning the four layers of materials through a patterned photoresist layer using a suitable etching process (such as a dry etching process, a wet etching process, other suitable processes, or combinations thereof). Other suitable materials and/or processes for forming the dummy gate portions 15 are within the contemplated scope of the present disclosure.

In sub-step S1023, each pair of the gate spacers 16 are respectively formed at two opposite sides of a corresponding one of the dummy gate portions 15 in the X direction. In some embodiments, each of the gate spacers 16 may be formed as a single layer structure or a multi-layered structure. In addition, a first pair of the source/drain recesses 17 (i.e., first source/drain recesses 171) are formed in the first stacks 121 of the stack units 12 (see also FIG. 2), a second pair of the source/drain recesses 17 (i.e., second source/drain recesses 172) are formed in the second stacks 122 of the stack units 12, and a third pair of the source/drain recesses 17 (i.e., third source/drain recesses 173) are formed in the third stacks 123 of the stack units 12. In some embodiments, as shown in FIG. 6, each of the first, second and third source/drain recesses 171, 172, 173 extends into an upper part of a corresponding one of the first, second and third fin portions 111, 112, 113.

In some embodiments, sub-step S1023 may include conformally depositing dielectric material(s) for forming the gate spacers 16 over the structure obtained after sub-step S1022 using, for example, CVD, ALD, or other suitable deposition techniques, followed by an anisotropic dry etching process until an upper surface of each of the dummy gate portions 15 and portions of the uppermost one of the stack units 12 are exposed such that the remaining dielectric material(s) remained at the opposite sides of the dummy gate portions 15 serve as the gate spacers 16. Afterwards, the exposed portions of the uppermost one of the stack units 12 and the structure disposed therebeneath are etched away using a first etching process (such as a dry etching process, a wet etching process, other suitable processes, or combinations thereof) so as to form the first, second and third source/drain recesses 171, 172, 173. The first source/drain recesses 171 are located at the two opposite sides of the dummy gate portion 15A, the second source/drain recesses 172 are located at the two opposite sides of the dummy gate portion 15C, and the third source/drain recesses 173 are located at the two opposite sides of the dummy gate portion 15E. In some embodiments, the dielectric materials for forming the gate spacers 16 may include a suitable low-k material (such as the examples described in the preceding paragraph), but is not limited thereto. Other suitable materials for the gate spacers 16 are within the contemplated scope of the present disclosure. Other suitable processes for forming the gate spacers 16 and the source/drain recesses 17 are within the contemplated scope of the present disclosure.

After sub-step S1023, as shown in FIG. 6, the channel films 1201 and the sacrificial films 1202 of the first stacks 121 are respectively patterned into first channel layers 51 and first sacrificial layers 52; the channel films 1201 and the sacrificial films 1202 of the second stacks 122 are respectively patterned into second channel layers 61 and second sacrificial layers 62; and the channel films 1201 and the sacrificial films 1202 of the third stacks 123 are respectively patterned into third channel layers 71 and third sacrificial layers 72.

In some embodiments, as shown in FIG. 6. the first channel layers 51 beneath the dummy gate portion 15A are together referred to as a first channel portion 50, the second channel layers 61 beneath the dummy gate portion 15C are together referred to as a second channel portion 60, and the third channel layers 71 beneath the dummy gate portion 15E are together referred to as a third channel portion 70.

In some embodiments, after sub-step S1023, the remaining dielectric material(s) remained on the two insulating portions 14 serve as a plurality pairs of fin sidewalls 18 (three pairs of the fin sidewalls 18 can be also observed in FIGS. 37 to 39), each pair of which are respectively disposed on the insulating portions 14 and disposed aside two opposite sides of a corresponding one of the source/drain recesses 171, 172, 173.

Referring to FIG. 1 and the examples illustrated in FIGS. 7 to 11, the method 100 proceeds to step S103, where a plurality of inner spacers 19, a plurality pairs of source/drain portions 53, 63, 73, a plurality of contact etching stop portions 20 and a plurality of inter-layer dielectric (ILD) portions 21 are formed. FIGS. 7 and 8 are views respectively similar to those of FIGS. 5 and 6, but illustrating the structures after step S103. FIG. 8 is a schematic cross-sectional view taken along line B-B of FIG. 7, and FIGS. 9 to 11 are schematic cross-sectional views respectively taken along lines B1-B1, B2-B2, B3-B3 of FIG. 7.

In some embodiments, step S103 may include sub-steps S1031 to S1034.

In sub-step S1031, the first, second and third sacrificial layers 52, 62, 72 are recessed through the first, second and third source/drain recesses 171, 172, 173 (see FIG. 6) to form lateral recesses (not shown). Recessing the first, second and third sacrificial layers 52, 62, 72 may be simultaneously performed using an isotropic etching process, such as wet etching, or other suitable etching techniques. After sub-step S1031, the remaining first, second and third sacrificial layers are respectively denoted by 521, 621, 721, as shown in FIG. 8.

In sub-step S1032, the inner spacers 19 are formed to separate the remaining first, second and third sacrificial layers 521, 621, 721 from the source/drain portions 53, 63, 73 to be subsequently formed. In some embodiments, the inner spacers 19 may be formed by (i) depositing a dielectric material (not shown) for forming the inner spacers 19 on the structure obtained after sub-step S1031 to fill the lateral recesses by CVD, ALD, or other suitable deposition techniques, and (ii) removing excess portions of the dielectric material by an etching process, for example, but not limited to, a wet etching process, a dry etching process, other suitable etching techniques, or combinations thereof, thereby forming the inner spacers 19 respectively in the lateral recesses. In some embodiments, the dielectric material for forming the inner spacers 19 includes silicon oxide, silicon nitride, silicon oxynitride, other suitable dielectric materials, or combinations thereof. Other dielectric materials suitable for the inner spacers 19 are within the contemplated scope of the present disclosure.

In sub-step S1033, as shown in FIG. 8, a first pair of the source/drain portions (i.e., first source/drain portions 53), a second pair of the source/drain portions (i.e., second source/drain portions 63), and a third pair of the source/drain portions (i.e., third source/drain portions 73) are respectively formed in the first, second and third source/drain recesses 171, 172, 173 (see FIG. 6). Formation of the first, second and third source/drain portions 53, 63, 73 may be performed using an epitaxial growth process including CVD, molecular-beam epitaxy (MBE), an epitaxial deposition/partial etch process, such as a cyclic deposition-etch (CDE) process and/or a selective epitaxial growth (SEG) process, but is not limited thereto.

After sub-step S1033, as shown in FIG. 8, the first source/drain portions 53 formed on the first fin portion 111 are located at two opposite sides of the first channel portion 50 which are opposite to each other in the X direction. Each of the first channel layers 51 extends between the first source/drain portions 53. The second source/drain portions 63 formed on the second fin portion 112 are located at two opposite sides of the second channel portion 60 which are opposite to each other in the X direction. Each of the second channel layers 61 extends between the second source/drain portions 63. The third source/drain portions 73 formed on the third fin portion 113 are located at two opposite sides of the third channel portion 70 which are opposite to each other in the X direction. Each of the third channel layers 71 extends between the third source/drain portions 73. It is noted that each of the source/drain portions 53, 63, 73 may refer to a source or a drain, individually or collectively dependent upon the context.

Each pair of the source/drain portions 53, 63, 73 may be independently doped with an n-type impurity or a p-type impurity to have an n-type conductivity or a p-type conductivity, and may be formed as a single layer structure or a multi-layered structure having several sub-layers with different doping concentration. One pair of the source/drain portions 53, 63, 73, when having an n-type conductivity to function as a source/drain of an n-FET, may include single crystalline silicon, polycrystalline silicon or other suitable materials doped with an n-type impurity. The n-type impurity may be, for example, but not limited to, nitrogen (N), phosphorous (P), arsenic (As), antimony (Sb), other suitable materials, or combinations thereof. One pair of the source/drain portions 53, 63, 73, when having a p-type conductivity to function as a source/drain of a p-FET, may include single crystalline or polycrystalline silicon, single crystalline or polycrystalline silicon germanium, or other suitable materials doped with a p-type impurity. The p-type impurity may be, for example, but not limited to, boron (B), aluminum (Al), gallium (Ga), indium (In), other suitable materials, or combinations thereof. The source/drain portions with different types of impurities may be separately formed.

In sub-step S1034, the contact etching stop portions 20 and the ILD portions 21 are sequentially and respectively formed on the source/drain portions 53, 63, 73 by sequentially depositing a contact etching stop layer (not shown) and an ILD layer (not shown) sequentially over the structure obtained after sub-step S1033 using a blanket deposition process, such as, but not limited to, CVD or molecular layer deposition (MLD), followed by a planarization process, for example, but not limited to, CMP, thereby removing the hard mask film 154 and the polish stop layer 153 (see FIGS. 5 and 6) of each of the dummy gate portions 15 and exposing the dummy gate electrode 152 of each of the dummy gate portions 15. Thereafter, the contact etching stop layer is formed into the contact etching stop portions 20, and the ILD layer is formed into the ILD portions 21. In some embodiments, the contact etching stop portions 20 may include, for example, but not limited to, silicon nitride, carbon-doped silicon nitride, other suitable materials, or combinations thereof. In some embodiments, the ILD portions 21 may include a dielectric material such as, but not limited to, silicon oxide, silicon nitride, silicon oxynitride, other suitable materials, or combinations thereof. Other suitable materials for the contact etching stop portions 20 and the ILD portions 21 are within the contemplated scope of the present disclosure.

Referring to FIG. 1 and the examples illustrated in FIGS. 12 to 31, the method 100 proceeds to step S104, where a replacement gate process is performed such that the remaining dummy gate portions 15 (see FIG. 7) are partially or completely replaced with a plurality of gate structures 90 (see FIG. 27), respectively, thereby obtaining the first, second and third devices 5, 6, 7. Each of the gate structures 90 including a gate dielectric layer 901 and a gate feature 902 disposed on the gate dielectric layer 901 (see FIGS. 29 to 31). FIGS. 27 and 28 are views respectively similar to FIGS. 7 and 8, but illustrating the structures after step S104. FIG. 28 is a schematic cross-sectional view taken along line C-C of FIG. 27.

In some embodiments, step S104 may include sub-steps S1041 to S1046.

FIGS. 12 to 14 are views similar to those of FIGS. 9 to 11, but illustrating the structures after sub-step S1041. In sub-step S1041, the dummy gate electrodes 152 of the remaining dummy gate portions 15 (see FIG. 8) are etched back for a period of time by a second etching process (such as dry etching, wet etching, other suitable processes, or combinations thereof) to form a plurality of cavities (e.g., three of the cavities 801 shown in FIGS. 12 to 14). After sub-step S1041, in FIGS. 12 to 14, the etched back dummy gate electrodes of the remaining dummy gate portions 15A, 15C, 15E are denoted by 152A. Each of the remaining sacrificial layers 521, 621, 721 has an upper surface and a lower surface which are respectively distal from and proximate to the semiconductor substrate 10. The dummy gate electrode 152A of the remaining dummy gate portion 15A has an upper surface at a level which is at least lower than that of the lower surface of an uppermost one of the first remaining sacrificial layers 521 and higher than that of the upper surface of a middle one of the first remaining sacrificial layers 521.

FIGS. 15 to 17 are views similar to those of FIGS. 12 to 14, but illustrating the structures after sub-step S1042. In sub-step S1042, a patterned photoresist layer 811 is formed to at least protect the dummy gate electrode 152A of the remaining dummy gate portion 15A and to at least expose the dummy gate electrodes 152A of the remaining dummy gate portions 15C, 15E obtained after sub-step S1041, and then the dummy gate electrodes 152A of the remaining dummy gate portions 15C, 15E obtained after sub-step S1041 are further etched back for a period of time by a process similar to the above-mentioned second etching process. Thereby, the cavities 801 at the regions 102, 103 (see FIGS. 13 and 14) are respectively formed into cavities 802. In some embodiments, the patterned photoresist layer 811 is formed to cover the structure on the region 101 of the semiconductor substrate 10 (see FIG. 8). In this case, the etched back dummy gate electrodes of the remaining dummy gate portions 15B, 15D obtained after sub-step S1041 and exposed from the patterned photoresist layer 811 may be further etched back in this sub-step (see also FIG. 27). After sub-step S1042, in FIGS. 16 and 17, the dummy gate electrodes of the remaining dummy gate portions 15C, 15E which are etched back twice are denoted by 152B. The dummy gate electrode 152B of the remaining dummy gate portion 15C has an upper surface at a level which is at least lower than that of the lower surface of the middle one of the second remaining sacrificial layers 621 and higher than that of the upper surface of the bottommost one of the second remaining sacrificial layers 621. After sub-step S1042, the patterned photoresist layer 811 is removed.

FIGS. 18 to 20 are views similar to those of FIGS. 15 to 17, but illustrating the structures after sub-step S1043. In sub-step S1043, a patterned photoresist layer 812 is formed to at least protect the dummy gate electrodes 152A, 152B of the remaining dummy gate portions 15A, 15C and to at least expose the dummy gate electrode 152B of the remaining dummy gate portions 15E obtained after sub-step S1042 (see also FIG. 17), and then the dummy gate electrode 152B of the remaining dummy gate portion 15E obtained after sub-step S1042 is completely removed by a process similar to the above-mentioned second etching process. Thereby, the cavity 802 at the third region 103 (see FIG. 17) is formed into a cavity 803. In some embodiments, the patterned photoresist layer 812 is formed to cover the structure on the regions 101, 102 of the semiconductor substrate 10 (see FIG. 8). In this case, the etched back dummy gate electrode of the remaining dummy gate portion 15D obtained after sub-step S1042 and exposed from the patterned photoresist layer 812 may be further etched back in this sub-step. After sub-step S1043, the patterned photoresist layer 812 is removed.

FIGS. 21 to 23 are views similar to those of FIGS. 18 to 20, but illustrating the structures after sub-step S1044. In sub-step S1044, portions of the dummy gate dielectric films 151 of the remaining dummy gate portions 15A, 15C which are respectively exposed from the elements 152A, 152B, and the entire dummy gate dielectric film 151 of the remaining dummy gate portion 15E are removed by dry etching, wet etching, other suitable processes, or combinations thereof. After sub-step S1044, as shown in FIGS. 21 to 23, the uppermost one of the first remaining sacrificial layers 521 is accessible through the cavity 801, the two uppermost ones of the second remaining sacrificial layers 621 are accessible through the cavity 802, and all of the third remaining sacrificial layers 721 are accessible through the cavity 803, such that the accessible sacrificial layers 521, 621, 721 as abovementioned may be subsequently removed. In addition, the dummy gate dielectric films 151 of the remaining dummy gate portions 15B, 15D may be partially or fully removed to permit corresponding ones of the first, second and third sacrificial layers originally located beneath the dummy gate portions 15B, 15D to be accessible after sub-step S1044.

FIGS. 24 to 26 are views similar to those of FIGS. 21 to 23, but illustrating the structures after sub-step S1045. In sub-step S1045, the accessible sacrificial layers 521, 621, 721 are removed by a process similar to the above-mentioned first etching process. Thereby, the cavities 801, 802, 803 shown in FIGS. 21 to 23 are respectively formed into cavities 804. After sub-step S1045, as shown in FIGS. 24 to 26, upper and lower surfaces of each of an uppermost one of the first channel layers 51, two uppermost ones of the second channel layers 61, and all of the third channel layers 71 are accessible through the cavities 804.

In sub-step S1046, the gate structures 90 are formed, thereby obtaining the first, second and third devices 5, 6, 7, as shown in FIG. 27. FIGS. 29 to 31 are views similar to those of FIGS. 24 to 26, but illustrating the structures after sub-step S1046. FIGS. 29 to 31 are schematic cross-sectional views respectively taken along lines C1-C1, C2-C2, C3-C3 of FIG. 27. For better illustration, as shown in FIG. 27, (i) the gate structure (i.e., first gate structure) formed to partially replace the dummy gate portion 15A is denoted by 90A, (ii) the gate structure formed to replace the dummy gate portion 15B is denoted by 90B, (iii) the gate structure (i.e., second gate structure) formed to partially replace the dummy gate portion 15C is denoted by 90C, (iv) the gate structure formed to replace the dummy gate portion 15D is denoted by 90D, and (iv) the gate structure (i.e., third gate structure) formed to replace the dummy gate portion 15E (see FIG. 7) is denoted by 90E. To be specific, as shown in FIGS. 29 to 31, the first, second and third gate structures 90A, 90C, 90E respectively formed in the cavities 804 (see FIGS. 24 to 26). In some embodiments, sub-step S1046 may include (i) sequentially depositing materials for forming the gate dielectric layer 901 and the gate feature 902 to fill the cavities obtained after sub-step S1045 (e.g., the cavities 804 shown in FIGS. 24 to 26) by a blanket deposition process, such as ALD, CVD or MLD, and (ii) performing a planarization process, for example, but not limited to, CMP, to remove excesses of the materials for forming the gate feature 902 and the gate dielectric layer 901 and to expose the ILD portions 21 (see FIG. 27), and (iii) etching back the materials for forming the gate dielectric layer 901 and the gate feature 902 using for example, but not limited to, dry etching, wet etching, other suitable processes, or combinations thereof, thereby obtaining the gate structures 90.

In some embodiments, the gate dielectric layer 901 includes silicon oxide, silicon nitride, silicon oxynitride, a suitable high-k material (such as the examples described in the preceding paragraph), other suitable materials, or combinations thereof. Other suitable materials for the gate dielectric layer 901 are within the contemplated scope of the present disclosure. In some embodiments, the gate feature 902 may be configured as a multi-layered structure including at least one work function metal which is provided for adjusting threshold voltage of an n-FET or a p-FET, an electrically conductive material having a low resistance which is provided for reducing electrical conductivity of the gate feature 902, other suitable materials, or combinations thereof. In some embodiments, the work function metal of the gate feature 902 of each of the gate structures 90 for forming an n-FET may be different from that for forming a p-FET so as to permit the n-FET and the p-FET to have different threshold voltages. Other suitable methods for adjusting the threshold voltages are within the contemplated scope of the present disclosure. In some embodiments, the gate feature 902 includes a metal material (e.g., tungsten (W), titanium (Ti), tantalum (Ta), aluminum (Al), or ruthenium (Ru)), metal-containing nitrides (e.g., titanium nitride (TiN), or tantalum nitride (TaN)), metal-containing silicides (e.g., nickel silicide (NiSi)), metal-containing carbides (e.g., tantalum carbide (TaC)), or combinations thereof. Other suitable materials for the gate feature 902 are within the contemplated scope of the present disclosure.

After sub-step S1046, as shown in FIGS. 29 to 31, the first gate structure 90A is disposed around the uppermost one of the first channel layers 51, the second gate structure 90C is disposed around two uppermost ones of the second channel layers 61, and the third gate structure 90E is disposed around all of the third channel layers 71.

Referring to FIGS. 27 and 29, among the first channel layers 51 each extending between the first source/drain portions 53, two surfaces of the uppermost one of the first channel layers 51, which are opposite to each other in the Z direction, are adjacent to and/or in contact with the first gate structure 90A. Therefore, the uppermost one of the first channel layers 51 serves as a first effective channel layer 51E. The first effective channel layer 51E, the first source/drain portions 53 and the first gate structure 90A together constitute the first device 5.

Referring to FIGS. 27 and 30, among the second channel layers 61 each extending between the second source/drain portions 63, two surfaces of each of the two uppermost ones of the second channel layers 61, which are opposite to each other in the Z direction, are adjacent to and/or in contact with the second gate structure 90C. Therefore, the two uppermost ones of the second channel layers 61 serve as second effective channel layers 61E. The second effective channel layers 61E, the second source/drain portions 63 and the second gate structure 90C together constitute the second device 6.

Referring to FIGS. 27 and 31, among the third channel layers 71 each extending between the third source/drain portions 73, two surfaces of each of the third channel layers 71, which are opposite to each other in the Z direction, are adjacent to and/or in contact with the third gate structure 90E. Therefore, the third channel layers 71 serve as third effective channel layers 71E. The third effective channel layers 71E, the third source/drain portions 73 and the third gate structure 90E together constitute the third device 7.

It can be seen that the first, second and third effective channel layers 51E, 61E, 71E may have a channel width that is substantially the same with the lengths L1, L2, L3, respectively, as described above with reference to FIG. 2. In some embodiments, as shown in FIG. 28, the first, second and third gate structures 90A, 90C, 90E have the same gate length in the X direction; in some other embodiments, the gate length of the third gate structure 90E may be less than that of the second gate structure 90C, and the gate length of the second gate structure 90C may be less than that of the first gate structure 90A.

It is briefly summarized that (i) the number of the effective channel layers in the third device 7 is greater than that in the second device 6, and the number of the effective channel layers in the second device 6 is greater than that in the first device 5, and that (ii) the channel width of the effective channel layers in the third device 7 is greater than that in the second device 6, and the channel width of the effective channel layers in the second device 6 is greater than that in the first device 5. Accordingly, the third device 7 may meet the requirement of high computing speed requirement, and the first device 5 may meet the requirement of low power consumption. Provision of a plurality of the devices (for example, but not limited to, three of the devices 5, 6, 7 are manufactured in the present disclosure) with different electrical performance allow more possibilities for circuit design. It is worth noting that in addition to some known factors (for example, but not limited to, materials of metal gate and gate dielectric, gate length, channel width, etc.) used to adjust electrical properties (for example, but not limited to, threshold voltage, saturated current, off current, etc.) of the devices, the number of the effective channel layers is also an available factor to adjust the electrical properties of the devices. For example, compared to each of the devices 5, 6, the device 7 may have (i) a shorter gate length in the X direction, (ii) a larger number of the effective channel layers, and (iii) a lower threshold voltage, and thus can be functioned to have a higher speed performance.

It is noted that when forming a plurality of the different type devices (assuming that the different type devices have different numbers of effective channel layers, and that the number of the different types is N, where N is an integer not less than 2) on a single one of the elongated fin 11 using the method 100 described above with reference to FIG. 2 to FIGS. 31, the number of the stack units 12 is at least N, and the number of the patterned photoresist layers for removing the dummy gate portions 15 is N−1.

In some embodiments, step S104 further includes depositing a dielectric material for forming a plurality of self-aligned dielectric features 903 on the structure obtained after formation of the gate structures 90 using a blanket deposition process, such as, but not limited to, CVD, ALD, or other suitable deposition techniques, followed by a planarization process, for example, but not limited to, CMP, or other suitable processes, to expose the ILD portions 21, thereby obtaining the self-aligned dielectric features 903 respectively disposed on the gate structures 90. In some embodiments, the dielectric material for forming the self-aligned dielectric features 903 include silicon oxide, silicon nitride, silicon oxynitride, but is not limited thereto.

In some non-shown embodiments, a plurality of the devices 5, a plurality of the devices 6, and a plurality of the devices 7, each being shown in FIG. 33, are formed on a single one of the elongated fin 11. Two adjacent ones of the gate structures 90A of the devices 5 are arranged at a first contacted poly pitch (CPP1). Two adjacent ones of the gate structures 90C of the devices 6 are arranged at a second contacted poly pitch (CPP2) which is larger than the CPP1. Two adjacent ones of the gate structures 90E of the devices 7 are arranged at a third contacted poly pitch (CPP3) which is larger than the CPP2. In some embodiments, a ratio of the CPP2 to the CPP1 may ranges from about 1.05 to about 1.2. In some embodiments, a ratio of the CPP3 to the CPP2 may ranges from about 1.05 to about 1.2.

Referring to FIG. 1 and the examples illustrated in FIGS. 32 to 36, the method 100 proceeds to step S105, where a plurality of gate isolation portions 22 (two of which are shown in FIG. 32) are formed to replace the gate structures 90B, 90D so as to permit the second device 6 to be electrically isolated from the first and third devices 5, 7, and a plurality of contact portions 23 are respectively formed on the source/drain portions 53, 63, 73, thereby obtaining the semiconductor structure 2. FIGS. 32 and 33 are views respectively similar to those of FIGS. 27 and 28, but illustrating the structures after step S105. FIGS. 33 to 36 are schematic cross-sectional views respectively taken along lines D-D, D1-D1, D2-D2, D3-D3 of FIG. 32 in accordance with some embodiments. The structures shown in FIGS. 29 to 31 are substantially not changed after step S105.

Each of the gate isolation portions 22 is made of a dielectric material. The examples of the dielectric material are similar to those for forming the insulating portions 14, and thus details thereof are omitted for the sake of brevity. The gate isolation portions 22 are each elongated in the Y direction. In some embodiments, as shown in FIG. 33, one of the gate isolation portions 22 extends downwardly into a connected region between the first and second fin portions 111, 112, and the other one of the gate isolation portions 22 extends downwardly into a connected region between the second and third fin portions 112, 113. In some embodiments, as shown in FIG. 32, a bottom surface of each of the gate isolation portions 22 may be at a level higher than a bottom surface of each of the insulating portions 14. In some embodiments, as shown in FIG. 33, each of the gate isolation portions 22 has a bottom surface at a level lower than a bottom surface of each of the source/drain portions 53, 63, 73, so as to electrically isolate the first, second, and third devices 5, 6, 7 from one another.

In some embodiments, step S105 may include sub-steps of: (i) forming a patterned photoresist layer on the structure obtained after step S104 to expose the self-aligned dielectric features 903 formed on the gate structures 90B, 90D (see FIG. 27) using spin-coating followed by a lithography process; (ii) performing an etching process (through the patterned photoresist by dry etching, wet etching, other suitable processes, or combinations thereof) to remove the exposed self-aligned dielectric features 903, the gate structures 90B, 90D and the elements which are wrapped by the gate structures 90B, 90D until the fin portions 111, 112, 113 beneath the gate structures 90B, 90D are partially removed so as to form trenches (not shown); (iii) depositing the dielectric material for forming the gate isolation portions 22 to fill the trenches, followed by a planarization process, for example, but not limited to, CMP, to remove an excess of the dielectric material until the ILD portions 21 are exposed, thereby obtaining the gate isolation portions 22; (iv) performing an etching process (for example, but not limited to, dry etching, wet etching, or a combination thereof) through another patterned photoresist layer to form openings (not shown), each extending through a corresponding one of the ILD portions 21 and a corresponding one of the contact etching stop portions 20 shown in FIG. 32 to expose a corresponding one of the source/drain portions 53, 63, 73 (see FIG. 33); (v) filling a conductive material for forming the contact portions 23 in the openings using for example, but not limited to, ALD, CVD, plating, or other suitable techniques; and (vi) removing an excess of the conductive material to expose the remaining self-aligned dielectric features 903 and the gate isolation portions 22 using CMP or other suitable techniques to form the contact portions 23. In some embodiments, an inter-metal dielectric (IMD) layer (not shown) may be formed on the structure obtained after sub-step (vi) of step S105, and then a plurality of contact vias (not shown) are formed in the IMD layer, such that the contact vias are permitted to be electrically connected to the contact portions 23, respectively.

In some embodiments, the conductive material for forming the contact portions 23 and the contact vias may include, for example, but not limited to, W, Al, Ru, cobalt (Co), copper (Cu), palladium (Pd), nickel (Ni), platinum (Pt), a low resistivity metal constituent, or the like, or combinations thereof. In some embodiments, the IMD layer may be made of a dielectric material similar to the dielectric material of the ILD portions 21, and thus details thereof are omitted for the sake of brevity. Other suitable materials and/or processes for forming the contact portions 23 and the contact vias are within the contemplated scope of the present disclosure. For example, in some embodiments, a metal silicide feature (not shown) is formed between each of the source/drain portions 53, 63, 73 and a corresponding one of the contact portions 23 for reducing a contact resistance (Rcsd) between each of the source/drain portions 53, 63, 73 and the corresponding contact portion 23. In some embodiments, the metal silicide feature may include titanium silicide, ruthenium silicide, nickel silicide, cobalt silicide, molybdenum silicide, or combinations thereof. Other suitable materials for the metal silicide feature are within the contemplated scope of the present disclosure.

It is worth mentioning that, as shown in FIG. 33, portions of the first, second and third fin portions 111, 112, 113 still remain in position beneath the gate isolation portions 22 after step S105, and thus a connection between the fin portions 111, 112 and a connection between the fin portions 112, 113 can be observed after step S105.

In some embodiments, the devices 5, 6, 7 of the at least one device assembly 3 have different numbers of the effective channel layers 51E, 61E, 71E which have substantially the same channel widths. In some other embodiments, the devices 5, 6, 7 of the at least one device assembly 3 have the same number of the effective channel layers 51E, 61E, 71E which have different channel widths.

In yet other embodiments, the devices 5, 6, 7 of the at least one device assembly 3 have different numbers of the effective channel layers 51E, 61E, 71E which have different channel widths. To be specific, in the at least one device assembly 3, a first one of the devices 5, 6, 7 may have a first number of the effective channel layers 51E, 61E, 71E and a first channel width, and a second one of the devices 5, 6, 7 may have a second number of the effective channel layers 51E, 61E, 71E and a second channel width. The second number is greater than the first number, and the second channel width is greater than the first channel width. In addition, a difference value between the first and second numbers may range from about 1 to about 5, and a ratio of the second channel width to the first channel width may range from about 1.1 to about 3. In some embodiments, in the at least one device assembly 3, each of the contact portions 23 formed on the first one of the devices 5, 6, 7 may have a first MD width, and each of the contact portions 23 formed on the second one of the devices 5, 6, 7 may have a second MD width that is larger than the first MD width. A ratio of the second MD width to the first MD width may range from about 1.1 to about 1.4. As shown in FIGS. 34 to 36, the contact portions 23 (one of which is shown) of the device 5 has a MD width less than that of the device 6, and the contact portions 23 (one of which is shown) of the device 6 has a MD width less than that of the device 7. In some embodiments, when viewing the at least one device assembly 3 from the Z direction, each of the contact vias formed on the first one of the devices 5, 6, 7 may occupy a first area, and each of the contact vias formed on the second one of the devices 5, 6, 7 may occupy a second area that is larger than the first area. A ratio of the second area to the first area may range from about 1.1 to about 2.5.

In some embodiments, the semiconductor structure 2 includes a plurality of the device assemblies 3 (one of which is shown in FIG. 32) disposed on the semiconductor substrate 10. The at least one elongated fin of one of the device assemblies 3 and the at least one elongated fin of an adjacent one of the device assemblies 3 are discontinuous and separated from each other in the X or Y directions.

In some other embodiments, each of the devices 5, 6, 7 of a first one of the device assemblies 3 has the same number (third number) of the effective channel layers 51E, 61E, 71E, and each of the devices 5, 6, 7 of a second one of the device assemblies 3 has the same number (fourth number) of the effective channel layers 51E, 61E, 71E. The fourth number is greater than the third number by, for example, about 1 to about 5. In some alternative embodiments, each of the devices 5, 6, 7 of the first one of the device assemblies 3 has the same channel width (third channel width), and each of the devices 5, 6, 7 of the second one of the device assemblies 3 has the same channel width (fourth channel width). The fourth channel width is greater than the third channel width. A ratio of the fourth channel width to the third channel width ranges from about 1.1 to about 3.

In the case that the patterned structure 1 shown in FIG. 4 is obtained in step S101, a first selective one of the devices 5, 6, 7 shown in FIGS. 32 and 33 may be formed on the first fin portion 111 of each of the elongated fins 11, and a second selective one of the devices 5, 6, 7 may be formed on the main part 112A. In some embodiments, the first selective one of the devices 5, 6, 7 has a fifth number of the effective channel layers and a fifth channel width, and the second selective one of the devices 5, 6, 7 has a sixth number of the effective channel layers and a sixth channel width. The sixth number is greater than the fifth number by, for example, about 1 to about 5, and a ratio of the sixth channel width to the fifth channel width ranges from about 1.5 to about 10. In addition, after formation of the devices on the patterned structure 1 shown in FIG. 4, two gate isolation portions (not shown, but similar to the gate isolation portions 22) may be respectively formed along two imaginary lines M1 and M2 shown in FIG. 4 so as to permit the device on the first fin portion 111 of each of the elongated fins 11 to be electrically isolated from the device on the main part 112A. To be specific, one of the gate isolation portions extends downwardly into a connection region between the connected part 112B and the first fin portion 111 of each of the elongated fins 11; and the other one of the gate isolation portions extends downwardly into a connection region between the connected part 112B and the main part 112A. Formation of the devices and the gate isolation portions on the patterned structure 1 shown in FIG. 4 is similar to those formed on the patterned structure 1 shown in FIG. 2, and the details thereof are omitted for the sake of brevity.

In the following, a first variant of the method 100 for manufacturing a first variant of the semiconductor structure 2A (see FIGS. 55 and 56) is illustrated. FIGS. 37 to 56 illustrate schematic views of intermediate stages of the first variant of the method 100 in accordance with some embodiments. Similar numerals from the above-mentioned embodiments have been used where appropriate, with some construction differences being indicated with different numerals. Some repeating structures are omitted in FIGS. 37 to 56 for the sake of brevity.

The first variant of the semiconductor structure 2A shown in FIGS. 55 and 56 has a structure similar to that of the semiconductor structure 2 shown in FIGS. 32 and 33, but has the differences as described in the following.

The remaining sacrificial layers 521, 621 shown in FIG. 33 are absent in the first variant of the semiconductor structure 2A, so that the first and second gate portions 90A, 90C are respectively disposed around the first and second channel portions 50, 60 to have a configuration similar to the third gate portion 90E shown in FIG. 31. In addition, the semiconductor structure 2A further includes first and second shielding elements 31, 32 each of which is disposed between one of the first and second fin portions 111, 112 and a corresponding one of the first and second source/drain portions 53, 63.

In some embodiments, the first and second shielding elements 31, 32 are made of an intrinsic or undoped semiconductor material, that is, a semiconductor material without being doped with impurities. In some embodiments, the first and second shielding elements 31, 32 may be made of a material the same as the first semiconductor material or the material of the elongated fin 11.

In some embodiments, as shown in FIG. 56, each of the first shielding elements 31 has an upper surface at a level not higher than a lower surface of the uppermost one of the first channel layers 51. That is, the uppermost one of the first channel layers 51 can function as the first effective channel layer 51E, and has two opposite ends, which are opposite to each other in the X direction, and which are not shielded by the first shielding elements 31, respectively, while a remainder of the first channel layers 51 extends between the first shielding elements 31, and serves as a first dummy channel feature because the first shielding elements 31 have no extra electrons or holes to serve as carriers transported therein. The first dummy channel feature includes two bottommost ones of the first channel layers 51 each having two opposite ends which are opposite to each other in the X direction, and which are shielded by the first shielding elements 31, respectively.

Each of the second shielding elements 32 has an upper surface at a level not higher than a lower surface of a middle one of the second channel layers 61 of the second channel portion 60. That is, each of the two bottommost ones of the second channel layers 61 can function as the second effective channel layer 61E and has two opposite ends, which are opposite to each other in the X direction, and which are not shielded by the second shielding elements 32, respectively, while a remainder of the second channel layers 61 extends between the second shielding elements 32, and serves as a second dummy channel feature because the second shielding elements 32 have no extra electrons or holes to serve as carriers transported therein. The second dummy channel feature includes a bottommost one of the channel layers 61 and has two opposite ends which are opposite to each other in the X direction, and which are shielded by the second shielding elements 32, respectively.

The first variant of the method 100 may include steps S111 to S115.

Steps S111 and S112 are respectively similar to steps S101 and S102 as described above with reference to FIGS. 2 to 6, and thus details thereof are omitted for the sake of brevity. The structure obtained after step S112 is similar to that shown in FIGS. 5 and 6, and FIGS. 37 to 39 are schematic cross-sectional views respectively taken along lines A1-A1. A2-A2, A3-A3 of FIG. 5.

Referring to the examples illustrated in FIGS. 40 to 53, the first variant of the method 100 proceeds to step S113, where the inner spacers 19, the first and second shielding elements 31, 32, the source/drain portions 53, 63, 73, the contact etching stop portions 20 and the ILD portions 21 are formed.

In some embodiments, step S113 includes sub-steps S1131 to S1135.

Sub-steps S1131 and S1132 are respectively similar to sub-steps S1031 and S1032, and thus details thereof are omitted for the sake of brevity. FIG. 40 is a view similar to that of FIG. 6, but illustrating the structure after step S1132. The structures shown in FIGS. 37 to 39 are substantially not changed after sub-step S1132.

In sub-step S1133, referring to FIGS. 40 and 50, the first and second shielding elements 31, 32 are shown to be respectively formed in the first and second source/drain recesses 171, 172. Sub-step S1133 may be performed by (i) forming a patterned mask layer 813 to cover the structures on the second and third regions 102, 103, as shown in FIGS. 41 to 44, (ii) forming the first shielding elements 31 in the first source/drain recesses 171 (see FIG. 37) by a process similar to the above-mentioned epitaxial growth process, (iii) removing the patterned mask layer 813 by dry etching, wet etching, or other suitable processes, (iv) forming a patterned mask layer 814 to cover the structures on the first and third regions 101, 103, as shown in FIGS. 45 to 48, (v) forming the second shielding elements 32 in the second source/drain recesses 172 (see FIG. 38) by a process similar to the above-mentioned epitaxial growth process, and (vi) removing the patterned mask layer 814 by dry etching, wet etching, or other suitable processes. It is noted that the epitaxial growth process used for forming the first and second shielding elements 31, 32 may be a cyclic deposition-etch (CDE) process. Through controlling deposition and etching parameters in deposition-etch cycles during formation of the first shielding elements 31, the material of the first shielding elements 31 formed to cover the first channel layers 51 in a deposition cycle may be subsequently removed in a subsequent etching cycle, such that the first shielding elements 31 may mainly grow upwardly from the first fin portions 111, and may be not formed to cover the uppermost one of the first channel layers 51. Likewise, during formation of the second shielding elements 32, the two uppermost ones of the second channel layers 61 may be not covered by the second shielding elements 32. In some embodiments, the patterned mask layer 813, 814 may be made of a dielectric material, for example, but not limited to, silicon nitride, silicon carbide, silicon oxynitride, silicon oxycarbide, silicon oxycarbonitride, aluminum oxide, or combinations thereof.

Sub-steps S1134 and S1135 are respectively similar to sub-steps S1033 and S1034, and thus details thereof are omitted for the sake of brevity. FIGS. 49 and 50 are views respectively similar to those of FIGS. 7 and 8, but illustrating the structure which is additionally subjected to sub-step S1133. FIGS. 50 to 53 are schematic cross-sectional view respectively taken along lines E-E, E1-E1, E2-E2, E3-E3 of FIG. 49.

It is noted that since each of the first and second source/drain portions 53, 63 may be made of a semiconductor material similar to that of the first and second shielding elements 31, 32, but are doped with an n-type impurity or a p-type impurity, all of the first and second shielding elements 31, 32 and the first and second source/drain portions 53, 63 may be formed by a process similar to the above-mentioned epitaxial growth process. Therefore, each of the first and second source/drain portions 53, 63 is epitaxially grown upward from an outer surface of a corresponding one of the first and second shielding elements 31, 32.

Referring to the example illustrated in FIG. 54, the first variant of the method 100 proceeds to step S114, where a replacement gate process is performed. FIG. 54 is a view similar to that of FIG. 49, but illustrating the structure after step S114. FIG. 54 is a view similar to that of FIG. 27, but each of the remaining dummy gate portions 15 (see FIG. 49) are completely replaced by the gate structures 90, respectively.

In some embodiments, step S114 includes sub-steps S1141 and S1142.

In some embodiments, step S114 is similar to step S104, but sub-step S1041 to S1045 are replaced with sub-step S1141. In sub-step S1141, the dummy gate electrode 152 and the dummy gate dielectric film 151 of each of the remaining dummy gate portions 15 and the first, second and third sacrificial layers 521, 621, 721 shown in FIG. 50 are removed to form a plurality of cavities (not shown) using dry etching, wet etching, other suitable processes, or combinations thereof. Afterwards, in sub-step S1142, formation of the gate structures 90 may be formed in the cavities in a manner similar to that of sub-step S1046.

Referring to the examples illustrated in FIGS. 55 and 56, the first variant of the method 100 proceeds to step S115, where the gate isolation portions 22 and the contact portions 23 are formed. Step S115 is similar to step S105, and thus details thereof are omitted for the sake of brevity. FIG. 55 is a view similar to that of FIG. 54, but illustrating the structure after sub-step S115. FIG. 56 is a schematic cross-sectional view taken along line F-F of FIG. 55.

Referring to FIG. 56, it can be seen that although in the first device 5, two surfaces of each of the first channel layers 51, which are opposite to each other in the Z direction, are adjacent to and/or in contact with the first gate portion 90A, the uppermost one of the first channel layers 51 that extends between the first source/drain portions 53 can serve as the first effectively channel layer 51E. Likewise, in the second device 6, the two uppermost ones of the second channel layers 61 extending between the second source/drain portions 63 can serve as the second effective channel layers 61E. In the third device 7, all the third channel layers 71 extending between the third source/drain portions 73 can serve as the third effective channel layers 71E.

Briefly summarized, the number of the effective channel layer(s) in the first, second and third devices 5, 6, 7 obtained by the method 100 may be also obtained by the first variant of the method 100.

It is noted that when forming a plurality of the devices (assuming that the different type devices have different numbers of effective channel layers, and that the number of the different types is N, where N is an integer not less than 2) on a single one of the elongated fin 11 using the first variant of the method 100, the number of the stack units 12 is at least N, and the number of the patterned mask layers for forming the shielding elements 31, 32 is N−1.

In the following, a second variant of the method 100 for manufacturing a second variant of the semiconductor structure 2B (see FIGS. 75 and 76) is illustrated. FIGS. 57 to 76 illustrate schematic views of intermediate stages of the second variant of the method 100 in accordance with some embodiments. Similar numerals from the above-mentioned embodiments have been used where appropriate, with some construction differences being indicated with different numerals. Some repeating structures are omitted in FIGS. 57 to 76 for the sake of brevity.

The second variant of the semiconductor structure 2B shown in FIGS. 75 and 76 has a structure similar to that of the first variant of the semiconductor structure 2A shown in FIGS. 55 and 56, but has the differences as described in the following.

In the second variant of the semiconductor structure 2B, each of the first and second shielding elements 31, 32 is made of a dielectric material, and the third device 7 further includes two dielectric elements 33, each of which is disposed between the third fin portion 113 and a corresponding one of the third source/drain portions 73. Each of the dielectric elements 33 is made of a dielectric material the same as that of the first and second shielding elements 31, 32, and is kept away from contact with the third effective channel layers 73E.

The second variant of the method 100 may include steps S121 to S125.

Steps S121 and S122 are respectively similar to steps S111 and S112 as described above, and thus details thereof are omitted for the sake of brevity. The structure obtained after step S122 is similar to that shown in FIGS. 5 and 6, and FIGS. 37 to 39.

Referring to the examples illustrated in FIGS. 57 to 73, the second variant of the method 100 proceeds to step S123, where the inner spacers 19, the shielding elements 31, 32, the dielectric elements 33, the source/drain portions 53, 63, 73, the contact etching stop portions 20, and the ILD portions 21 are formed.

In some embodiments, step S123 includes sub-steps S1231 to S1235.

Sub-steps S1231 and S1232 are respectively similar to sub-steps S1131 and S1132, and thus details thereof are omitted for the sake of brevity. The structure after sub-step S1232 is similar to that shown in FIGS. 37 to 40.

In sub-step S1233, as shown in FIGS. 66 to 68, each of the first and second shielding elements 31, 32 and the dielectric elements 33 is formed in a corresponding one of the source/drain recesses 171, 172, 173 (see FIGS. 37 to 39). Sub-step S1233 is performed by (i) forming a plurality of first dielectric segments 301 respectively in the first, second and third source/drain recesses 171, 172, 173 (see FIGS. 57 to 60), each of the first dielectric segments 301 having a first thickness, (ii) etching back the first dielectric segments 301 at the second region 102 through a first patterned photoresist layer (not shown), such that as shown in FIGS. 61 and 63, the etched back first dielectric segments 301A at the second region 102 has a second thickness less than the first thickness, and then removing the first patterned photoresist layer, (iii) etching back the first dielectric segments 301 at the third region 103 through a second patterned photoresist layer (not shown), such that as shown in FIGS. 61 and 64, such that the etched back first dielectric segments 301B at the third region 103 has a third thickness less than the second thickness, and then removing the second patterned photoresist layer (at this stage, the first dielectric segments 301, 301A, 301B are obtained at the first, second and third regions 101, 102, 103 as shown in FIGS. 62 to 64), and (iv) forming a plurality of second dielectric segments 302 respectively on the first dielectric segments 301, 301A, 301B. After sub-step S1233, as shown in FIGS. 65 to 68, the first shielding elements 31 each including the first and second dielectric segments 301, 302 are formed to block the two bottommost ones of the first channel layers 51. The second shielding elements 32 each including the first and second dielectric segments 301A, 302 are formed to block the bottommost one of the second channel layers 61. The dielectric elements 33, each including the first and second dielectric segments 301B, 302, are formed without being in contact with the third channel layers 71.

In some embodiments, formation of the first dielectric segments 301 may be performed by CVD which has a cyclic process including a deposition step, a plasma treatment step and then an etching step. At the beginning of sub-step S1233, the dielectric material of the first dielectric segments 301 may be conformally deposited on the structure after sub-step S1232, and then horizontal regions of the dielectric material may be densified by, for example, but not limited to, argon plasma or nitrogen plasma, in the plasma treatment step. Afterwards, vertical regions of the dielectric material with less densified can be removed in the etching step. Therefore, the first dielectric segments 301 may be formed upwardly from the fin portions 111, 112, 113 without covering the channel layers which are located above upper surfaces of the first dielectric segments 301. Likewise, formation of the second dielectric segments 302 may be formed in a manner similar to that of formation of the first dielectric segments 301.

Sub-steps S1234 and S1235 are respectively similar to sub-steps S1134 and S1135, and thus details thereof are omitted for the sake of brevity. FIGS. 69 and 70 are views respectively similar to those of FIGS. 49 and 50, but illustrating the structure after sub-step S1235. FIGS. 70 to 73 are schematic cross-sectional view respectively taken along lines G-G, G1-G1, G2-G2, G3-G3 of FIG. 69.

It is noted that since each of the first, second and third source/drain portions 53, 63, 73 can be epitaxially grown from the first, second and third channel layers 51, 61, 71, but are less likely grown from on the dielectric material (i.e., the elements 31, 32, 33), the configurations of the source/drain portions 53, 63, 73 in the second variant of the semiconductor structure 2B may be different from those in the first variant of the semiconductor structure 2A (see FIGS. 51 to 53).

Referring to the example illustrated in FIG. 74, the second variant of the method 100 proceeds to step S124, where a replacement gate process is performed. FIG. 74 is a view similar to that of FIG. 54, but illustrating the structure after step S124. Step S124 is similar to step S114, and thus details thereof are omitted for the sake of brevity.

Referring to the example illustrated in FIG. 75, the second variant of the method 100 proceeds to step S125, where the gate isolation portions 22 and the contact portions 23 are formed. FIG. 75 is a view similar to that of FIG. 55, but illustrating the structure after step S125. FIG. 76 is a schematic cross-sectional view taken along line H-H of FIG. 75. Step S125 is similar to step S115, and thus details thereof are omitted for the sake of brevity.

Briefly summarized, the number of the effective channel layer(s) in the first, second and third devices 5, 6, 7 obtained by the method 100 may be also obtained by the second variant of the method 100.

It is noted that when forming a plurality of the devices (assuming that the different type devices have different numbers of effective channel layers, and that the number of the different types is N, where N is an integer not less than 2) on a single one of the elongated fin 11 using the second variant of the method 100, the number of the stack units 12 is at least N, and the number of the patterned photoresist layers for etching back the first dielectric segments 301 is N−1.

In the following, a third variant of the method 100 for manufacturing a third variant of the semiconductor structure 2C (see FIGS. 91 and 92) is illustrated. FIGS. 77 to 95 illustrate schematic views of intermediate stages of the third variant of the method 100 in accordance with some embodiments. Similar numerals from the above-mentioned embodiments have been used where appropriate, with some construction differences being indicated with different numerals. Some repeating structures are omitted in FIGS. 77 to 95 for the sake of brevity.

The third variant of the semiconductor structure 2C shown in FIGS. 91 and 92 has a structure similar to that of the semiconductor structure 2 shown in FIGS. 32 and 33, but in the semiconductor structure 2C, each of the channel layers 51, 61, 71 in the channel portions 50, 60, 70 serves as the effective channel layers 51E, 61E, 71E. Thus, the channel layers 51, 61, 71 to be formed are controlled in the third variant of the method 100.

The third variant of the method 100 may include steps S131 to S135.

Referring to the examples illustrated in FIGS. 77 to 82, the third variant of the method 100 begins at step S131, where a variant of the patterned structure 4 is formed.

In some embodiments, step S131 may include sub-steps S1311 to S1316.

In sub-step S1311, as shown in FIG. 77, the starting substrate 40 includes first, second and third regions 401, 402, 403 displaced from each other in the X direction, and a first sacrificial part 411 is formed on the third region 403. The first sacrificial part 411 is made of a material which is the same as that of the sacrificial films 1202, and may have a thickness the same as that of the sacrificial films 1202. In some embodiments, the first sacrificial part 411 may be formed by (i) forming a material layer for forming the first sacrificial part 411 on the starting substrate 40 by CVD, ALD, epitaxial growth process, or other suitable deposition processes, and (ii) patterning the material layer through a patterned photoresist layer using a process similar to the above-mentioned first etching process to expose the first and second regions 401, 402 of the starting substrate 40.

In sub-step S1312, as shown in FIG. 78, a first material part 421 includes a first material region and a second material region which are respectively formed on the first and second regions 401, 402, and has an upper surface flush with that of the first sacrificial part 411. Afterwards, a second material part 422 includes a first material region, a second material region, and a third material region which are respectively formed on the first and second material regions of the first material part 421 and the first sacrificial part 411. In some embodiments, the first material part 421 is made of a material different from that of the sacrificial films 1202. In some embodiments, the first material part 421 may be made of a material the same as that of the starting substrate 40 and/or the channel films 1201, and may have a thickness the same as that of the channel films 1201. In some embodiments, the first and second material parts 421, 422 may be made of the same material. In some embodiments, the first and second material parts 421, 422 may be formed by (i) forming a material layer for forming the first material part 421 on the structure obtained after S1311 by CVD, ALD, epitaxial growth process, or other suitable deposition processes, followed by a planarization process, for example, but not limited to, CMP, to expose the first sacrificial part 411 to obtain the first material part 421, and (ii) forming the second material part 422 to cover the first material part 421 and the first sacrificial part 411 by CVD, ALD, epitaxial growth process, or other suitable deposition processes. Other suitable processes for sub-step S1312 are within the contemplated scope of the present disclosure.

In sub-step S1313, as shown in FIG. 79, a second sacrificial part 412 includes a first sacrificial region and a second sacrificial region which are respectively formed over the second and third material regions of the second material part 422 to expose the first material region of the second material part 422. The material and thickness of the second sacrificial part 412 may be the same as those of the first sacrificial part 411. In some embodiments, the second sacrificial part 412 may be formed by (i) forming a material layer for forming the second sacrificial part 412 on the structure obtained after sub-step S1312 by CVD, ALD, epitaxial growth process, or other suitable deposition processes, and (ii) patterning the material layer through a patterned photoresist layer using a process similar to the above-mentioned first etching process to expose the first material region of the second material part 422. Other suitable processes for sub-step S1313 are within the contemplated scope of the present disclosure.

In sub-step S1314, as shown in FIG. 80, a third material part 423 is formed on the first material region of the second material part 422, and has an upper surface flush with that of the second sacrificial part 412. Afterwards, a fourth material part 424 includes first, second and third material regions which are respectively formed over the third material part 423 and the first and second sacrificial regions of the second sacrificial part 412. In some embodiments, the third material part 423 is made of a material different from that of the sacrificial films 1202. In some embodiments, the third material part 423 may be made of a material the same as that of the starting substrate 40, and/or the channel films 1201, and may have a thickness the same as that of the channel films 1201. In some embodiments, the third and fourth material parts 423, 424 may be made of the same material. In some embodiments, the third and fourth material parts 423, 424 may be formed by (i) forming a material layer for forming the third material part 423 on the structure obtained after S1313 by CVD, ALD, epitaxial growth process, or other suitable deposition processes, followed by a planarization process, for example, but not limited to, CMP, to expose the second sacrificial part 412, thereby obtaining the third material part 423, and (ii) forming the fourth material part 424 to cover the third material part 423 and the second sacrificial part 412 by CVD, ALD, epitaxial growth process, or other suitable deposition processes. Other suitable processes for sub-step S1314 are within the contemplated scope of the present disclosure.

In sub-step S1315, as shown in FIG. 81, a stack assembly 43 and a hard mask layer 44 are sequentially formed on the fourth material part 424. The stack assembly 43 includes at least one repeating unit 430 (one of which is shown). The repeating unit 430 includes a channel material layer 431 and a sacrificial material layer 432 which are respectively distal from and proximate to the starting substrate 40. In some embodiments, the stack assembly 43 and the hard mask layer 44 may be formed by sequentially depositing materials for forming the stack assembly 43 and the hard mask layer 44 using CVD, ALD, epitaxial growth process, or other suitable deposition processes.

In sub-step S1316, as shown in FIG. 82, the structure obtained after sub-step S1315 is patterned to form into the patterned structure 4. In detail, the starting substrate 40 is patterned into the semiconductor substrate 10 and the elongated fin 11 which is disposed on the semiconductor substrate 10. The first region 401 is patterned into the first region 101 and the first fin portion 111. The second region 402 is patterned into the second region 102 and the second fin portion 112. The third region 403 is patterned into the third region 103 and the third fin portion 113.

The material part 423 and the first material regions of the material parts 421, 422, 424 are patterned into a first material portion 461 on the first fin portion 111. The second material regions of the material parts 421, 422 are patterned into a second material portion 462 on the second fin portion 112.

The second material region of the fourth material part 424 and the first sacrificial region of the second sacrificial part 412 are patterned into a first preformed stack 45A on the second material portion 462. The third material region of the second material part 422 and the first sacrificial part 411 are patterned into a second preformed stack 45B on the third fin portion 113. The third material region of the fourth material part 424 and the second sacrificial region of the second sacrificial part 412 are patterned into a third preformed stack 45C on the second preformed stack 45B. Each of preformed stacks 45A, 45B, 45C includes a channel film 451 and a sacrificial film 452 which are disposed distal from and proximate to the semiconductor substrate 10, respectively.

The repeating unit 430 and the hard mask layer 44 are respectively patterned into the stack unit 12 and the hard mask portion 13. A number of the stack unit(s) 12 is corresponding to that of the repeating unit(s) 430. The stack unit 12 includes the first, second and third stacks 121, 122, 123 formed respectively on the first material portion 461, the first preformed stack 45A, and the third preformed stack 45C.

It can be seen that after step S131, in the patterned structure 4 shown in FIG. 82, the single channel film 1201 is formed on the first fin portion 111, two of the channel films 1201, 451 are formed on the second fin portion 112, and three of the channel films 1201, 451 are formed on the third fin portion 113.

Referring to the examples illustrated in FIGS. 83 to 87, the third variant of the method 100 proceeds to step S132, where the insulating portions 14, the dummy gate portions 15, and the gate spacer 16 are formed, and the stack unit 12 and the preformed stacks 45A, 45B, 45C are patterned to form the source/drain recesses 171, 172, 173. FIG. 83 is a view similar to that of FIG. 82, but illustrating the structure after step S132. FIGS. 84 to 87 are schematic cross-sectional views taken along lines I-I, I1-I1, I2-I2, I3-I3 of FIG. 83.

In some embodiments, step S132 may include sub-steps S1321 to S1323. Sub-steps S1321 and S1322 are respectively similar to sub-steps S1021 and S1022, and thus details thereof are omitted for the sake of brevity.

Sub-step S1323 is similar to sub-step S1023, except the processes for forming the source/drain recesses 171, 172, 173 in sub-step 1323 which are described as follows. In some embodiments, as shown in FIG. 84, each of the first source/drain recesses 171 may extend through the first stack 121 into an upper part of the first material portion 461 to have a first depth, each of the second source/drain recesses 172 may extend through the second stack 122 and the preformed stack 45A into an upper part of the second material portion 462 to have a second depth, and each of the third source/drain recesses 173 may extend through the third stack 123 and the preformed stacks 45B, 45C into an upper part of the third fin portion 113 to have a third depth. After sub-step 1323, the channel film 1201 and the sacrificial film 1202 of the first stack 121 are patterned into the first channel layer 51 and the first sacrificial layer 52, the channel films 1201, 451 and the sacrificial films 1202, 452 of the second stack 122 and the first preformed stack 45A are patterned into the second channel layers 61 and the second sacrificial layers 62, and the channel films 1201, 451 and the sacrificial films 1202, 452 of the third stack 123 and the second and third preformed stacks 45B, 45C are patterned into the third channel layers 71 and the third sacrificial layers 72. In some embodiments, the third depth is deeper than the second depth, and the second depth is deeper than the first depth.

In some embodiments, sub-step S1323 may include (i) forming the gate spacers 16 as described in sub-step S1023, (ii) forming a first patterned photoresist layer to cover the structures at the first and second regions 101, 102 so as to expose the structure at the third region 103, (iii) selectively etching the patterned structure 4 shown in FIG. 82 through the first patterned photoresist layer for a period of time by a process similar to the above-mentioned first etching process, (iv) removing the first patterned photoresist layer, (v) forming a second photoresist layer to cover the structure at the first region 101 to expose the structures at the second and third regions 102, 103, (vi) selectively etching the patterned structure 4 through the second photoresist layer for a period of time by a process similar to the above-mentioned first etching process, (vii) removing the second patterned photoresist layer, (viii) selectively etching the patterned structure 4 for a period of time by a process similar to the above-mentioned first etching process, thereby obtaining the first, second and third source/drain recesses 171, 172, 173 with different depths. It is noted that as shown in FIGS. 85 to 87, since the patterned structure 4 at the first, second and third regions 101, 102, 103 are etched with different etching times, the fin sidewalls 18 at the first region 101 may have a height greater than that of the fin sidewalls 18 at the second region 102, and the fin sidewalls 18 at the second region 102 may have a height greater than that of the fin sidewalls 18 at the third region 103.

Referring to the example illustrated in FIG. 88, the third variant of the method 100 proceeds to step S133, where the inner spacers 19, the source/drain portions 53, 63, 73, the contact etching stop portions 20, and the ILD portions 21 are formed (see also FIG. 90). FIG. 88 is a view similar to that of FIG. 83, but illustrating the structure after step S133. Step S133 is similar to step S103, and thus details thereof are omitted for the sake of brevity.

Referring to the examples illustrated in FIGS. 89 and 90, the third variant of the method 100 proceeds to step S134, where the replacement gate process is performed. FIG. 89 is a view similar to that of FIG. 88, but illustrating the structure after step S134. FIG. 90 is schematic cross-sectional view taken along line J-J of FIG. 89. Step S134 is similar to step S114, and thus details thereof are omitted for the sake of brevity.

Referring to the examples illustrated in FIGS. 91 to 95, the third variant of the method 100 proceeds to step S135, where the gate isolation portions 22 and the contact portions 23 are formed. Step S135 is similar to step S105, and thus details thereof are omitted for the sake of brevity. FIGS. 91 and 92 are views respectively similar to those of FIGS. 89 and 90, but illustrating the structures after step S135. FIGS. 92 to 95 are schematic cross-sectional views respectively taken along lines K-K, K1-K1, K2-K2, K3-K3 of FIG. 91.

Briefly summarized, the number of the effective channel layer(s) in the first, second and third devices 5, 6, 7 obtained by the method 100 may be also obtained by the third variant of the method 100. As shown in FIG. 92, it can be seen that for the third variant of the semiconductor structure 2C, the number of the effective channel layers 51E, 61E, 71E can be adjusted by adjusting the number of the channel layers 51, 61, 71.

It is noted that when forming a plurality of the devices (assuming that the different type devices have different numbers of effective channel layers, and that the number of the different types is N, where N is an integer not less than 2) on a single one of the elongated fin 11 using the third variant of the method 100, (i) the number of the stack units 12 is at least N, (ii) the number of the patterned photoresist layers for forming the structure shown in FIG. 81 is N−1, and (iii) the number of the patterned photoresist layers for forming the source/drain recesses is N−1.

In some embodiments, some steps in the method 100, and the first, second, and third variants of the method 100 may be modified, replaced, or eliminated without departure from the spirit and scope of the present disclosure. In some alternative embodiments, the semiconductor structure 2, 2A, 2B, 2C may further include additional features, and/or some features present in the semiconductor structure 2, 2A, 2B, 2C may be modified, replaced, or eliminated without departure from the spirit and scope of the present disclosure.

For example, FIG. 96 illustrates a fourth variant of the semiconductor structure 2D in accordance with some embodiments. The semiconductor structure 2D has a structure similar to that shown in FIG. 33, but the semiconductor structure 2D further includes the first shielding elements 31 and the second shielding elements 32 shown in FIG. 56. Therefore, the source/drain portions 53, 63 in semiconductor structure 2D each has a size smaller than that of the source/drain portions 53, 63 shown in FIG. 33. The materials and processes for forming the elements 31, 32 and the source/drain portions 53, 63, 73 in the semiconductor structure 2D are similar to those described in the first variant of the method 100, and thus details thereof are omitted for the sake of brevity. In this case, a substrate leakage current between two adjacent one of the devices 5, 6, 7 may be reduced.

For another example, FIG. 97 illustrates a fifth variant of the semiconductor structure 2E in accordance with some embodiments. The semiconductor structure 2E has a structure similar to that shown in FIG. 33, but the semiconductor structure 2E further includes the first and second shielding elements 31, 32 and the dielectric elements 33 shown in FIG. 76. The materials and processes for forming the elements 31, 32, 33 and the source/drain portions 53, 63, 73 in the in semiconductor structure 2E are similar to those described in the second variant of the method 100, and thus details thereof are omitted for the sake of brevity. In this case, a substrate leakage current between two adjacent one of the devices 5, 6, 7 may be reduced as well.

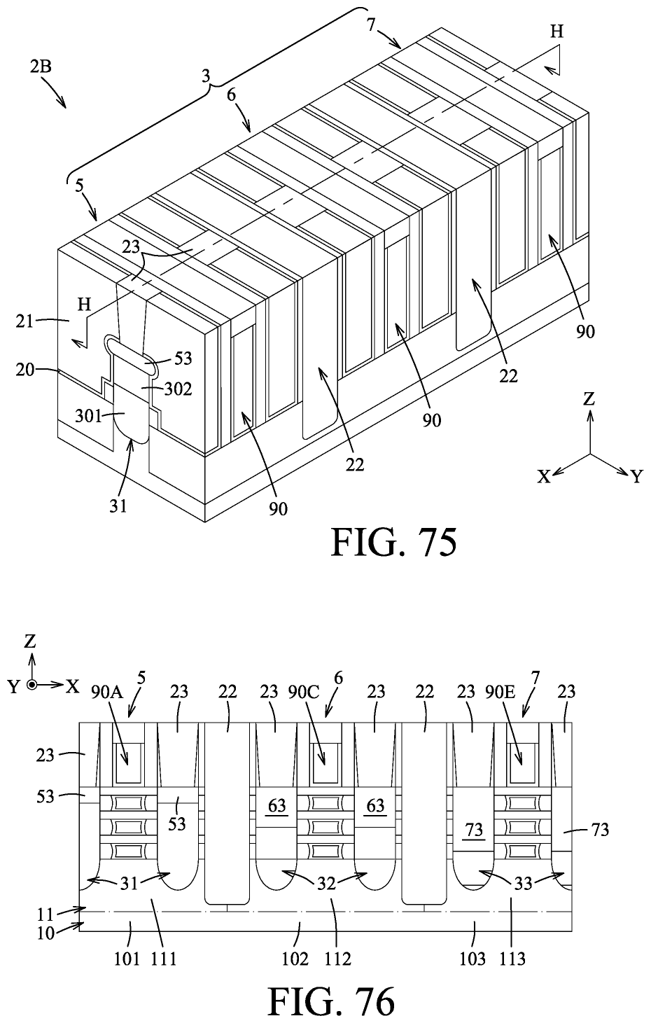

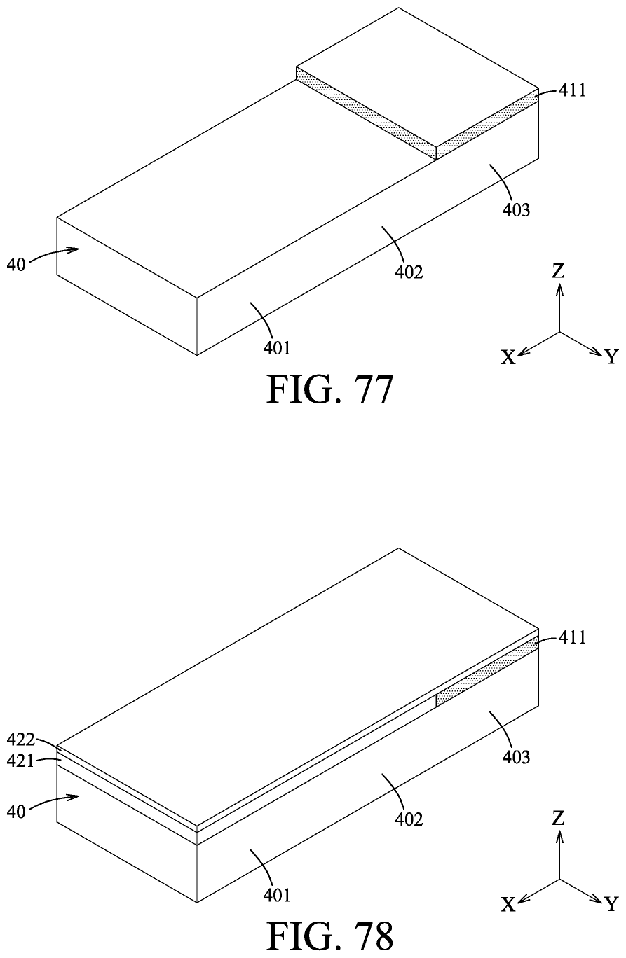

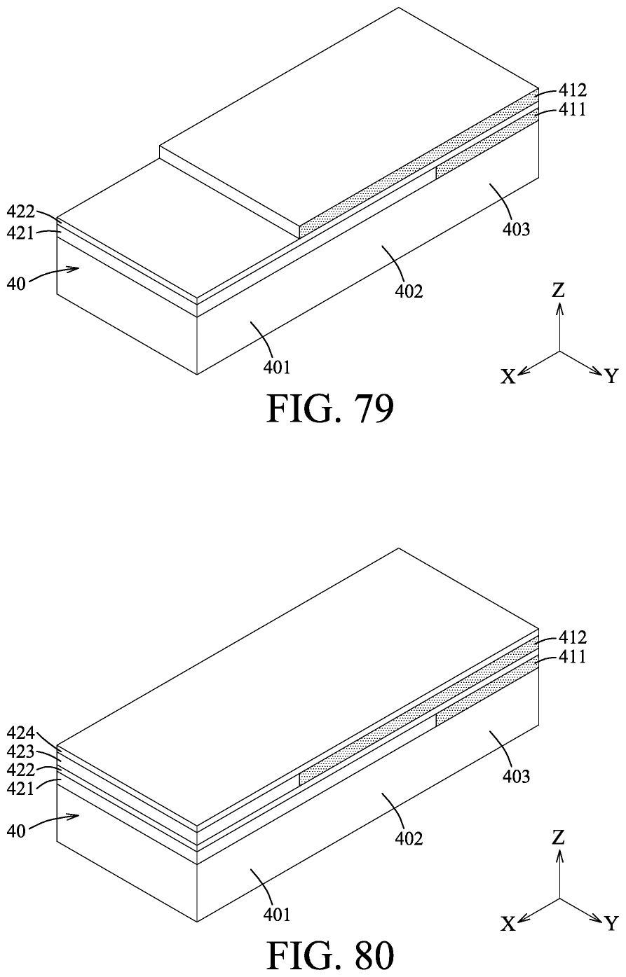

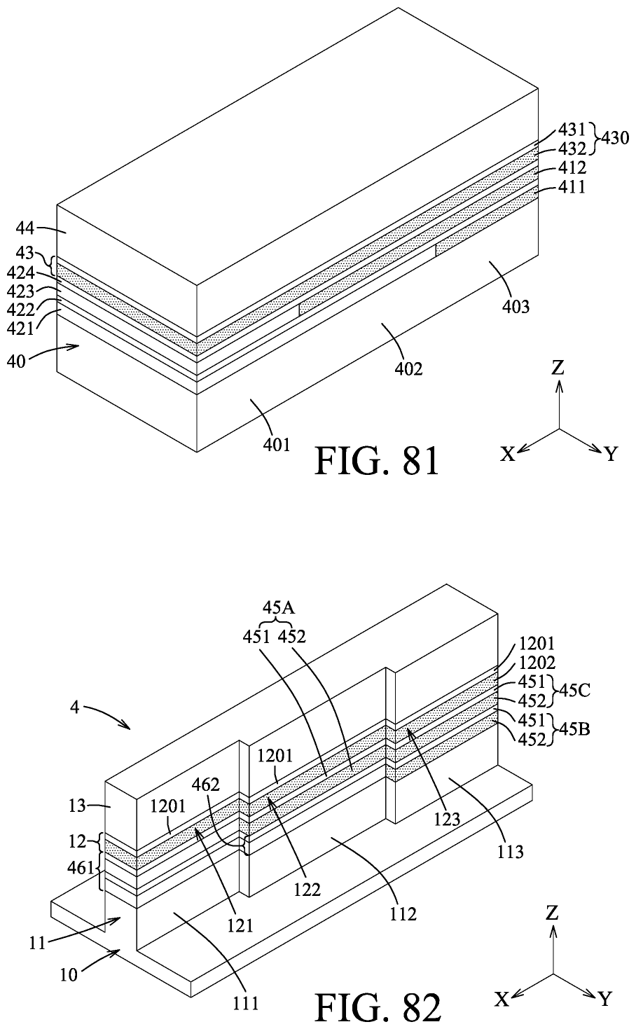

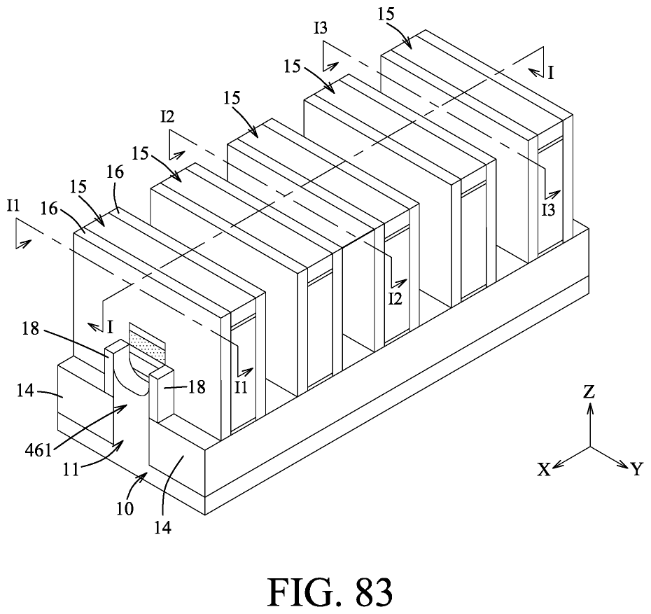

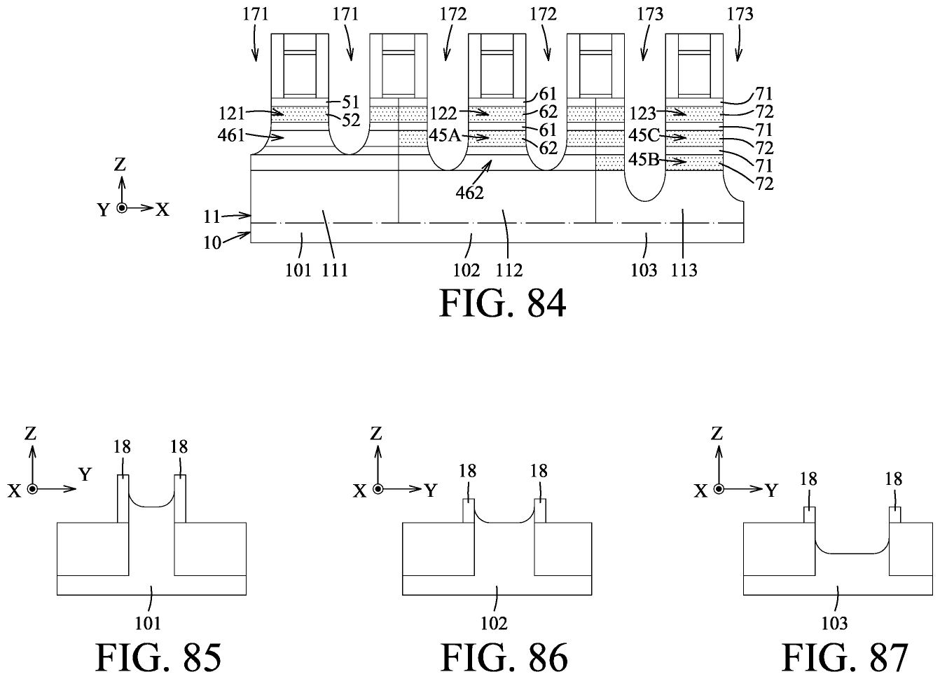

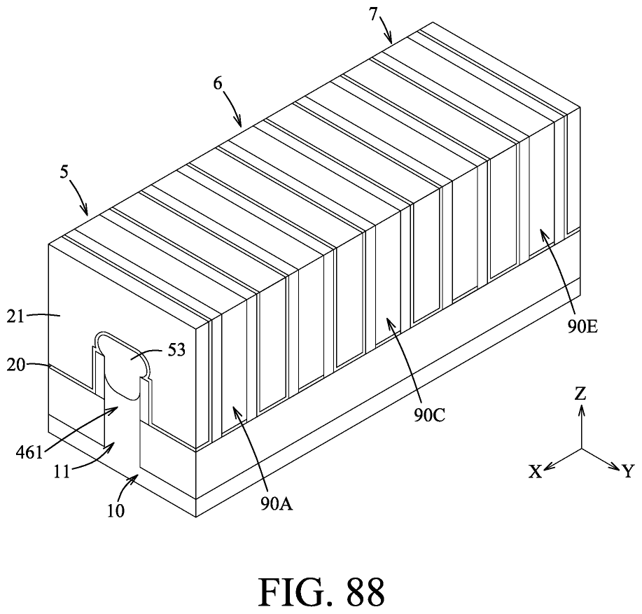

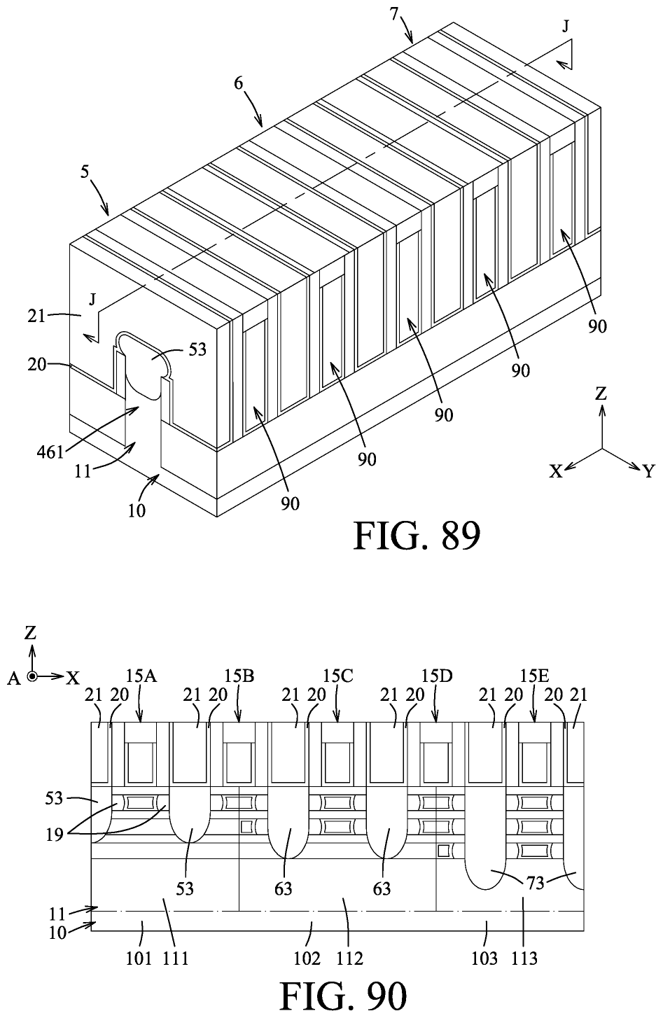

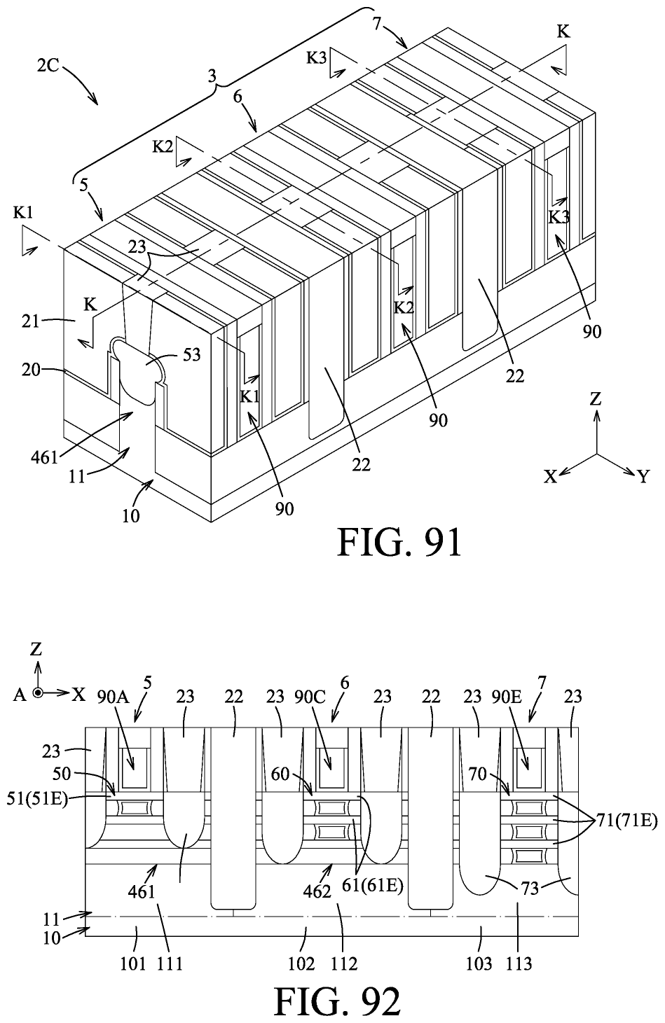

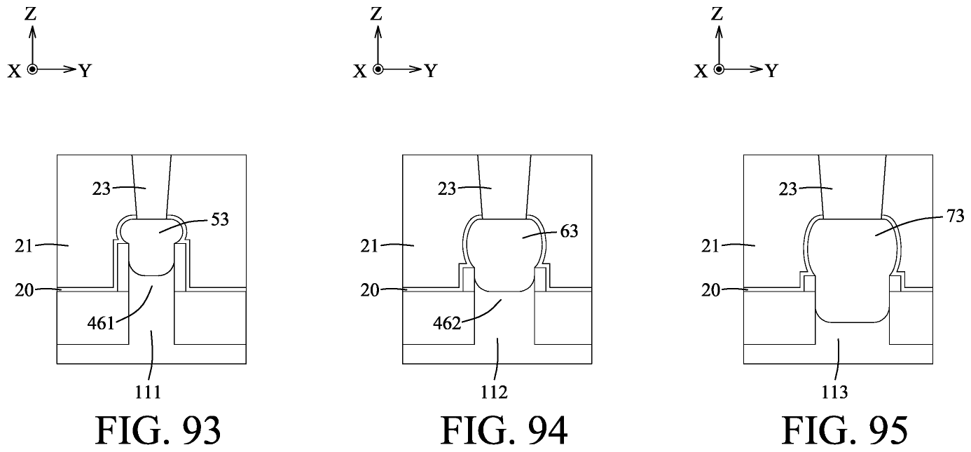

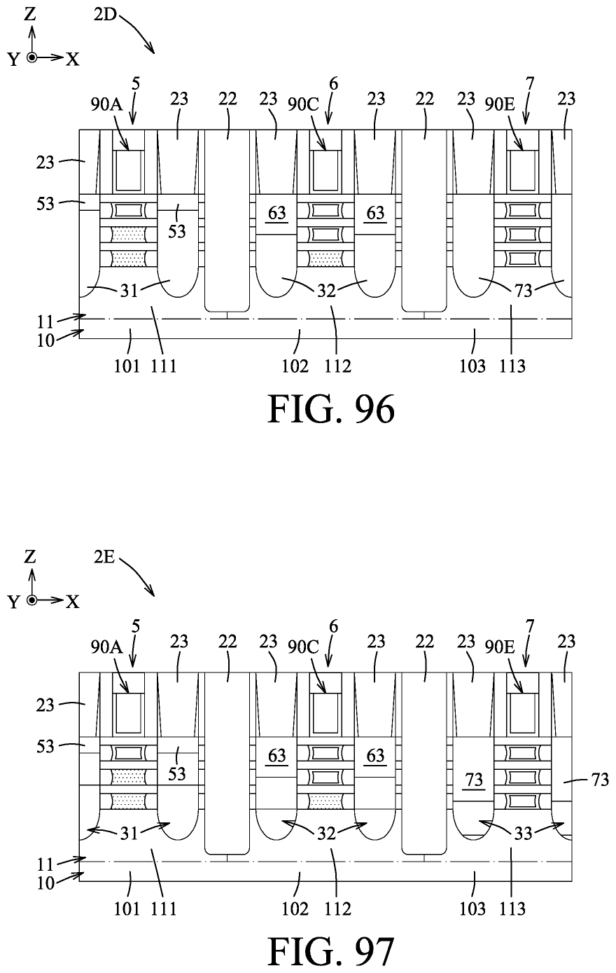

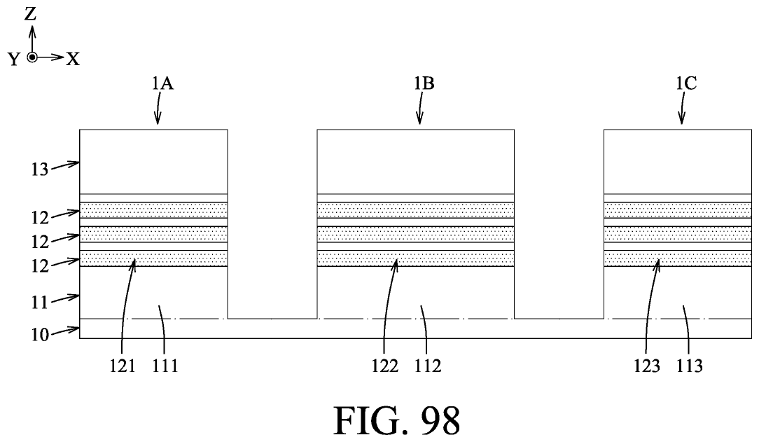

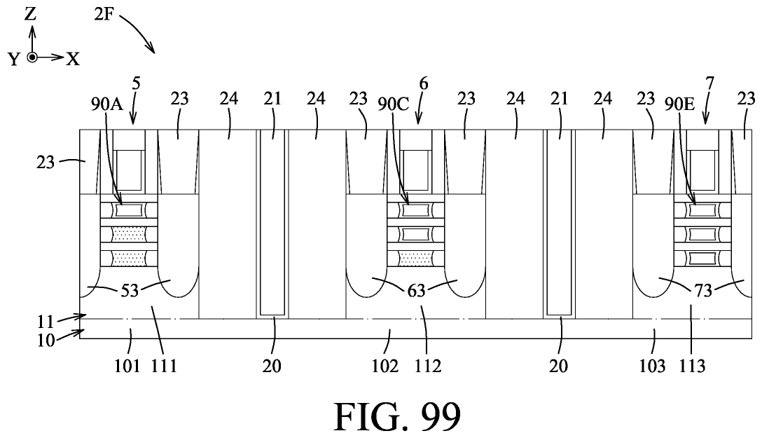

For yet another example, FIG. 99 illustrates a sixth variant of the semiconductor structure 2F in accordance with some embodiments. In some embodiments, at the first step of the method 100 (i.e., steps S101, S111, S121, S131), the patterned structure 1 or 4 shown in FIGS. 2 to 4 and 82 are patterned into first, second and third parts 1A, 1B, 1C which are separated from each other in the X direction, as shown in FIG. 98. During formation of the insulating portions 14 (see FIG. 5), the hard mask portion 13 shown in FIG. 98 are removed from the parts 1A, 1B, 1C. During formation of the dummy gate portions 15, each of the dummy gate portions 15B, 15D (for example, those shown in FIG. 8) may be formed into two dummy gate parts which are spaced apart from each other in the X direction (therefore, four dummy parts are formed). Each of the dummy gate parts has a configuration similar to each of the dummy gate portions 15. After the replacement gate process, the fourth dummy gate parts are formed into four gate structures (not shown), and then, the four gate structures and the elements wrapped thereby are replaced with four isolation segments 24 (therefore, the gate isolation portions 22 shown in FIGS. 32 and 33 are not formed). In this case, in the semiconductor structure 2F, at least two of the isolation segments 24 (two of which are shown in FIG. 99) are disposed between two adjacent ones of the devices 5, 6, 7 which are arranged in the X direction for structural isolation. Furthermore, a space between two adjacent ones of the isolation segments 24 may be filled by the contact etching stop portion 20 and the ILD portion 21.

In the semiconductor structure of this disclosure, a plurality of devices having different number of effective channels may be formed on the same row of the fin, and some two adjacent ones of the devices can be well isolated according to practical requirements. That is, different devices (having different performances) can be closely arranged in the same row of the fin, not only based on material selection of metal gate, introduction of dipole in gate dielectric layer, length of the metal gate, width of effective channel(s), but also based on the number of the effective channel(s). In addition, a plurality of methods for manufacturing the devices having different number of the effective channels are also disclosed, and any one or combinations of the methods can be used according to actual circuit design.

In accordance with some embodiments of the present disclosure, a method for manufacturing a semiconductor structure includes: forming an elongated fin on a semiconductor substrate, the elongated fin having a first fin portion with a first fin width and a second fin portion with a second fin width which is different from the first fin width; forming a first device on the first fin portion, the first device including a first channel portion which has at least one first effective channel layer; and forming a second device on the second fin portion, the second device including a second channel portion which has a plurality of second effective channel layers, a number of the second effective channel layers being greater than a number of the at least one first effective channel layer.

In accordance with some embodiments of the present disclosure, the first device further includes a pair of first source/drain portions disposed at two opposite sides of the first channel portion, and a first gate structure disposed around the at least one first effective channel layer such that an upper surface and a lower surface of the at least one first effective channel layer, which are respectively distal from and proximate to the semiconductor substrate, are both adjacent to the first gate structure. The second device further includes a pair of second source/drain portions disposed at two opposite sides of the second channel portion, and a second gate structure disposed around the second effective channel layers such that an upper surface and a lower surface of each of the second effective channel layers, which are respectively distal from and proximate to the semiconductor substrate, are both adjacent to the second gate structure.

In accordance with some embodiments of the present disclosure, the elongated fin is elongated in an X direction, and the first and second devices are formed by: forming at least one preformed stack on the second fin portion, the at least one preformed stack including a channel film and a sacrificial film disposed distal from and proximate to the semiconductor substrate, respectively, the channel film being made of a first semiconductor material, the sacrificial film being made of a second semiconductor material different from the first semiconductor material; forming a material portion on the first fin portion such that an upper surface of the material portion is flush with an upper surface of the at least one preformed stack, the material portion being made of a material the same as the first semiconductor material; forming at least one stack unit which includes a first stack on the material portion and a second stack on the at least one preformed stack, each of the first and second stacks including a channel film and a sacrificial film which are disposed distal from and proximate to the semiconductor substrate, respectively, and which are respectively made of a channel material and a sacrificial material that are respectively the same as the first and second semiconductor materials; forming the first source/drain portions in the first stack of the at least one stack unit such that the first source/drain portions are spaced apart from each other in the X direction, and such that the channel film and the sacrificial film of the first stack of the at least one stack unit are respectively formed into a first channel layer and a first sacrificial layer, the first channel layer serving as the at least one first effective channel layer; forming the second source/drain portions in the second stack of the at least one stack unit and the at least one preformed stack such that the second source/drain portions are spaced apart from each other in the X direction, and such that the channel films and the sacrificial films of the at least one preformed stack and the second stack of the at least one stack unit are respectively formed into second channel layers and second sacrificial layers, the second channel layers serving as the second effective channel layers; removing the first and second sacrificial layers; forming the first gate structure around the at least one first effective channel layer; and forming the second gate structure around the second effective channel layers.

In accordance with some embodiments of the present disclosure, the elongated fin is elongated in an X direction, and the first and second devices are formed by: forming a plurality of stack units each of which includes a first stack and a second stack respectively on the first fin portion and the second fin portion, each of the first and second stacks including a channel film made of a first semiconductor material, and a sacrificial film made of a second semiconductor material different from the first semiconductor material, the channel film and the sacrificial film of each of the first and second stacks being disposed distal from and proximate to the semiconductor substrate, respectively; forming a pair of first source/drain recesses in the first stacks of the stack units such that the first source/drain recesses are spaced apart from each other in the X direction, and such that the channel films and the sacrificial films of the first stacks of the stack units are respectively formed into first channel layers and first sacrificial layers; forming a pair of second source/drain recesses in the second stacks of the stack units such that the second the source/drain recesses are spaced apart from each other in the X direction, and such that the channel films and the sacrificial films of the second stacks of the stack units are respectively formed into second channel layers and second sacrificial layers; forming two shielding elements respectively in the first source/drain recesses such that an upper surface of each of the shielding elements is at a level not higher than a lower surface of an uppermost one of the first channel layers; forming the first source/drain portions respectively in the first source/drain recesses to cover the shielding elements such that the uppermost one of the first channel layers, which is disposed between the first source/drain portions, serves as the at least one first effective channel layer; forming the second source/drain portions in the second source/drain recesses such that the second channel layers, each of which is disposed between the second source/drain portions, serve as the second effective channel layers; removing the first and second sacrificial layers; forming the first gate structure around the at least one first effective channel layer; and forming the second gate structure around the second effective channel layers.

In accordance with some embodiments of the present disclosure, the shielding elements are made of a dielectric material or a material the same as the first semiconductor material

In accordance with some embodiments of the present disclosure, the elongated fin is elongated in an X direction, and the first device and the second devices are formed by: forming a plurality of stack units each of which includes a first stack and a second stack respectively on the first fin portion and the second fin portion, each of the first and second stacks including a channel film made of a first semiconductor material, and a sacrificial film made of a second semiconductor material different from the first semiconductor material, the channel film and the sacrificial film of each of the first and second stacks being disposed distal from and proximate to the semiconductor substrate, respectively; forming a pair of first source/drain portions in the first stacks of the stack units such that the first source/drain portions are spaced apart from each other in the X direction, and such that the channel films and the sacrificial films of the first stacks of the stack units are respectively formed into first channel layers and first sacrificial layers; forming a pair of second source/drain portions in the second stacks of the stack units such that the second source/drain portions are spaced apart from each other in the X direction, and such that the channel films and the sacrificial films of the second stacks of the stack units are respectively formed into second channel layers and second sacrificial layers; removing at least an uppermost one of the first sacrificial layers such that an uppermost one of the first channel layers serves as the at least one first effective channel layer; removing the second sacrificial layers such that the second channel layers serves as the second effective channel layers; forming the first gate structure around the at least one first effective channel layer; and forming the second gate structure around the second effective channel layers.

In accordance with some embodiments of the present disclosure, a method for manufacturing a semiconductor structure includes: forming an elongated fin on a semiconductor substrate, the elongated fin having a first fin portion and a second fin portion displaced from each other in a first direction; forming a first device on the first fin portion, the first device including two first source/drain portions which are spaced apart from each other in the first direction, a first channel portion including at least one first effective channel layer which extends between the first source/drain portions, and a first gate structure disposed around the at least one first effective channel layer such that two surfaces of the at least one first effective channel layer, which are opposite to each other in a second direction transverse to the first direction, are adjacent to the first gate structure; and forming a second device on the second fin portion, the second device including two second source/drain portions which are spaced apart from each other in the first direction, a second channel portion including a plurality of second effective channel layers each of which extends between the two second source/drain portions, the second effective channel layers being separated from each other in the second direction, and a second gate structure disposed around the second effective channel layers such that two surfaces of each of the second effective channel layers, which are opposite to each other in the second direction, are adjacent to the second gate structure, a number of the second effective channel layers being greater than a number of the at least one first effective channel layer.

In accordance with some embodiments of the present disclosure, the method further includes forming two insulating portions at two opposite sides of the elongated fin in a third direction transverse to the first and second directions such that each of the first and second fin portions is disposed between the two insulating portions. Each of the insulating portions is elongated in the first direction.

In accordance with some embodiments of the present disclosure, the method further includes forming a gate isolation portion between one of the first source/drain portions which is proximate to the second device and one of the second source/drain portions which is proximate to the first device. The gate isolation portion is elongated in a third direction transverse to the first and second directions.

In accordance with some embodiments of the present disclosure, the gate isolation portion has a bottom surface at a level lower than that of each of the first and second source/drain portions and higher than that of each of the insulating portions, such that the first and second fin portions are connected with each other.

In accordance with some embodiments of the present disclosure, the first and second fin portions respectively have a first fin width and a second fin width in a third direction transverse to the first and second directions. At least one first effective channel layer has a first channel width in the third direction, and each of the second effective channel layers has a second channel width in the third direction which is the same as the second fin width. The second channel width is greater than the first channel width.

In accordance with some embodiments of the present disclosure, the method further includes, before forming the first and second devices, patterning the elongated fin such that the first and second fin portions are arranged discontinuously in the first direction.

In accordance with some embodiments of the present disclosure, a semiconductor structure includes a semiconductor substrate; an elongated fin disposed on the semiconductor substrate, and having a first fin portion and a second fin portion which are displaced from each other in a first direction; a first device disposed on the first fin portion; and a second device disposed on the second fin portion. The first device includes two first source/drain portions spaced apart from each other in the first direction, a first channel portion including at least one first effective channel layer which extends between the two first source/drain portions, the first channel portion having a first width in a second direction transverse to the first direction, and a first gate structure disposed around the at least one first effective channel layer such that two surfaces of the at least one first effective channel layer, which are opposite to each other in a third direction transverse to the first and second directions, are adjacent to the first gate structure. The first gate structure includes a first gate feature, and a first gate dielectric layer disposed to separate the first gate feature from the at least one first effective channel layer. The second device includes two second source/drain portions spaced apart from each other in the first direction, a second channel portion including a plurality of second effective channel layers each of which extends between the two second source/drain portions, the second effective channel layers being separated from each other in the third direction, the second channel portion having a second width in the second direction, the second width being greater than the first width, and a second gate structure disposed around the second effective channel layers such that two surfaces of each of the second effective channel layers, which are opposite to each other in the third direction, are adjacent to the second gate structure, the second gate structure including a second gate feature, and a second gate dielectric layer disposed to separate the second gate feature from the second effective channel layers. A number of the second effective channel layers is greater than a number of the at least one first effective channel layer.

In accordance with some embodiments of the present disclosure, the first channel portion includes a plurality of first channel layers separated from each other in the third direction, and the second channel portion includes a plurality of second channel layers separated from each other in the third direction. A number of the first channel layers is equal to a number of the second channel layers. The first device further includes two shielding elements, each of which is disposed between the first fin portion and a corresponding one of the first source/drain portions. At least one of the first channel layers serves as the at least one first effective channel layer, and a remainder of the first channel layers extends between the first shielding elements, and serves as a first dummy channel feature. The first gate structure is disposed around the at least one first effective channel layer and the first dummy channel feature. All of the second channel layers serve as the second effective channel layers, respectively.

In accordance with some embodiments of the present disclosure, each of the shielding elements is made of an undoped semiconductor material.

In accordance with some embodiments of the present disclosure, each of the shielding elements is made of a dielectric material, and the second device further includes two dielectric elements, each of which is disposed between the second fin portion and a corresponding one of the second source/drain portions. The dielectric elements are made of a dielectric material the same as that of the shielding elements, and are kept away from contact with the second effective channel layers.

In accordance with some embodiments of the present disclosure, the first channel portion includes a plurality of first channel layers, and the second channel portion includes a plurality of second channel layers. A number of the first channel layers is equal to a number of the second channel layers. The first device further includes two first shielding elements, each of which is disposed between the first fin portion and a corresponding one of the first source/drain portions. The second device further includes two second shielding elements, each of which is disposed between the second fin portion and a corresponding one of the second source/drain portions. At least one of the first channel layers serves as the at least one first effective channel layer, and a remainder of the first channel layers extends between the first shielding elements, and serves as a first dummy channel feature. The first gate structure is disposed around the at least one first effective channel layer and the first dummy channel feature. At least two of the second channel layers serve as the second effective channel layers, and a remainder of the second channel layers extends between the second shielding elements, and serves as a second dummy channel feature. The second gate structure is disposed around the second effective channel layers and the second dummy channel feature.

In accordance with some embodiments of the present disclosure, each of the first and second shielding elements is made of an undoped semiconductor material or a dielectric material.

In accordance with some embodiments of the present disclosure, the first channel portion includes a plurality of first channel layers each of which extends between the first source/drain portions, and the second channel portion includes a plurality of second channel layers each of which extends between the second source/drain portions. A number of the first channel layers is equal to a number of the second channel layers. The first device further includes at least one sacrificial layer which at least shields a lower surface of a bottommost one of the first channel layers so as to permit at least an uppermost one of the first channel layers to serve as the at least one first effective channel layer. All of the second channel layers serve as the second effective channel features, respectively.

In accordance with some embodiments of the present disclosure, the first channel portion includes a plurality of first channel layers each of which extends between the first source/drain portions, and the second channel portion includes a plurality of second channel layers each of which extends between the second source/drain portions. A number of the first channel layers is equal to a number of the second channel layers. The first device further includes at least two first sacrificial layers which at least shield lower surfaces of two bottommost ones of the first channel layers, respectively, so as to permit at least an uppermost one of the first channel layers to serve as the at least one first effective channel layer. The second device further includes at least one second sacrificial layer which at least shields a lower surface of a bottommost one of the second channel layers so as to permit at least two uppermost ones of the second channel layers to serve as the second effective channel layers.

In accordance with some embodiments of the present disclosure, a semiconductor structure includes: a semiconductor substrate; an elongated fin disposed on the substrate and having a first fin portion and a second fin portion displaced from each other; a first device disposed on the first fin portion; and a second device disposed on the second fin portion. The first device includes two first source/drain portions which are spaced apart from each other and which are respectively proximate to and distal from the second fin portion, a first channel portion including at least one first effective channel layer extending between the first source/drain portions, and a first gate structure disposed around the at least one first effective channel layer such that a lower surface and an upper surface of the at least one first effective channel layer, which are respectively proximate to and distal from the semiconductor substrate, are adjacent to the first gate structure. The first gate structure includes a first gate feature, and a first gate dielectric layer disposed to separate the first gate feature from the at least one first effective channel layer. The second device includes two second source/drain portions spaced apart from each other and which are respectively proximate to and distal from the first fin portion, a second channel portion including a plurality of second effective channel layers each of which extends between the two second source/drain portions, and a second gate structure disposed around the second effective channel layers such that a lower surface and an upper surface of each of the second effective channel layers, which are respectively proximate to and distal from the semiconductor substrate, are adjacent to the second gate structure. The second gate structure includes a second gate feature, and a second gate dielectric layer disposed to separate the second gate feature from the second effective channel layers. A number of the second effective channel layers is greater than a number of the at least one first channel layer.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming an elongated fin on a semiconductor substrate, the elongated fin having a first fin portion with a first fin width and a second fin portion with a second fin width which is different from the first fin width;
forming a first device on the first fin portion, the first device including a first channel portion which has at least one first effective channel layer; and
forming a second device on the second fin portion, the second device including a second channel portion which has a plurality of second effective channel layers, a number of the second effective channel layers being greater than a number of the at least one first effective channel layer.

2. The method as claimed in claim 1, wherein:
the first device further includes
a pair of first source/drain portions disposed at two opposite sides of the first channel portion, and
a first gate structure disposed around the at least one first effective channel layer such that an upper surface and a lower surface of the at least one first effective channel layer, which are respectively distal from and proximate to the semiconductor substrate, are both adjacent to the first gate structure; and
the second device further includes
a pair of second source/drain portions disposed at two opposite sides of the second channel portion, and
a second gate structure disposed around the second effective channel layers such that an upper surface and a lower surface of each of the second effective channel layers, which are respectively distal from and proximate to the semiconductor substrate, are both adjacent to the second gate structure.

3. The method as claimed in claim 2, wherein the elongated fin is elongated in an X direction, and the first and second devices are formed by:
forming at least one preformed stack on the second fin portion, the at least one preformed stack including a channel film and a sacrificial film disposed distal from and proximate to the semiconductor substrate, respectively, the channel film being made of a first semiconductor material, the sacrificial film being made of a second semiconductor material different from the first semiconductor material;
forming a material portion on the first fin portion such that an upper surface of the material portion is flush with an upper surface of the at least one preformed stack, the material portion being made of a material the same as the first semiconductor material;
forming at least one stack unit which includes a first stack on the material portion and a second stack on the at least one preformed stack, each of the first and second stacks including a channel film and a sacrificial film which are disposed distal from and proximate to the semiconductor substrate, respectively, and which are respectively made of a channel material and a sacrificial material that are respectively the same as the first and second semiconductor materials;
forming the first source/drain portions in the first stack of the at least one stack unit such that the first source/drain portions are spaced apart from each other in the X direction, and such that the channel film and the sacrificial film of the first stack of the at least one stack unit are respectively formed into a first channel layer and a first sacrificial layer, the first channel layer serving as the at least one first effective channel layer;
forming the second source/drain portions in the second stack of the at least one stack unit and the at least one preformed stack such that the second source/drain portions are spaced apart from each other in the X direction, and such that the channel films and the sacrificial films of the at least one preformed stack and the second stack of the at least one stack unit are respectively formed into second channel layers and second sacrificial layers, the second channel layers serving as the second effective channel layers;
removing the first and second sacrificial layers;
forming the first gate structure around the at least one first effective channel layer; and
forming the second gate structure around the second effective channel layers.

4. The method as claimed in claim 2, wherein the elongated fin is elongated in an X direction, and the first and second devices are formed by:
forming a plurality of stack units each of which includes a first stack and a second stack respectively on the first fin portion and the second fin portion, each of the first and second stacks including a channel film made of a first semiconductor material, and a sacrificial film made of a second semiconductor material different from the first semiconductor material, the channel film and the sacrificial film of each of the first and second stacks being disposed distal from and proximate to the semiconductor substrate, respectively;
forming a pair of first source/drain recesses in the first stacks of the stack units such that the first source/drain recesses are spaced apart from each other in the X direction, and such that the channel films and the sacrificial films of the first stacks of the stack units are respectively formed into first channel layers and first sacrificial layers;
forming a pair of second source/drain recesses in the second stacks of the stack units such that the second the source/drain recesses are spaced apart from each other in the X direction, and such that the channel films and the sacrificial films of the second stacks of the stack units are respectively formed into second channel layers and second sacrificial layers;
forming two shielding elements respectively in the first source/drain recesses such that an upper surface of each of the shielding elements is at a level not higher than a lower surface of an uppermost one of the first channel layers;
forming the first source/drain portions respectively in the first source/drain recesses to cover the shielding elements such that the uppermost one of the first channel layers, which is disposed between the first source/drain portions, serves as the at least one first effective channel layer;
forming the second source/drain portions in the second source/drain recesses such that the second channel layers, each of which is disposed between the second source/drain portions, serve as the second effective channel layers;
removing the first and second sacrificial layers;
forming the first gate structure around the at least one first effective channel layer; and
forming the second gate structure around the second effective channel layers.

5. The method as claimed in claim 4, wherein the shielding elements are made of a dielectric material or a material the same as the first semiconductor material.

6. The method as claimed in claim 2, wherein the elongated fin is elongated in an X direction, and the first device and the second devices are formed by:
forming a plurality of stack units each of which includes a first stack and a second stack respectively on the first fin portion and the second fin portion, each of the first and second stacks including a channel film made of a first semiconductor material, and a sacrificial film made of a second semiconductor material different from the first semiconductor material, the channel film and the sacrificial film of each of the first and second stacks being disposed distal from and proximate to the semiconductor substrate, respectively;
forming a pair of first source/drain portions in the first stacks of the stack units such that the first source/drain portions are spaced apart from each other in the X direction, and such that the channel films and the sacrificial films of the first stacks of the stack units are respectively formed into first channel layers and first sacrificial layers;
forming a pair of second source/drain portions in the second stacks of the stack units such that the second source/drain portions are spaced apart from each other in the X direction, and such that the channel films and the sacrificial films of the second stacks of the stack units are respectively formed into second channel layers and second sacrificial layers;
removing at least an uppermost one of the first sacrificial layers such that an uppermost one of the first channel layers serves as the at least one first effective channel layer;
removing the second sacrificial layers such that the second channel layers serve as the second effective channel layers;
forming the first gate structure around the at least one first effective channel layer; and
forming the second gate structure around the second effective channel layers.

7. A method for manufacturing a semiconductor structure, comprising:
forming an elongated fin on a semiconductor substrate, the elongated fin having a first fin portion and a second fin portion displaced from each other in a first direction;
forming a first device on the first fin portion, the first device including
two first source/drain portions which are spaced apart from each other in the first direction,
a first channel portion including at least one first effective channel layer which extends between the first source/drain portions, and
a first gate structure disposed around the at least one first effective channel layer such that two surfaces of the at least one first effective channel layer, which are opposite to each other in a second direction transverse to the first direction, are adjacent to the first gate structure; and
forming a second device on the second fin portion, the second device including
two second source/drain portions which are spaced apart from each other in the first direction,
a second channel portion including a plurality of second effective channel layers each of which extends between the two second source/drain portions, the second effective channel layers being separated from each other in the second direction, and
a second gate structure disposed around the second effective channel layers such that two surfaces of each of the second effective channel layers, which are opposite to each other in the second direction, are adjacent to the second gate structure, a number of the second effective channel layers being greater than a number of the at least one first effective channel layer.

8. The method as claimed in claim 7, further comprising forming two insulating portions at two opposite sides of the elongated fin in a third direction transverse to the first and second directions such that each of the first and second fin portions is disposed between the two insulating portions, each of the insulating portions being elongated in the first direction.

9. The method as claimed in claim 8, further comprising forming a gate isolation portion between one of the first source/drain portions which is proximate to the second device and one of the second source/drain portions which is proximate to the first device, the gate isolation portion being elongated in a third direction transverse to the first and second directions.

10. The method as claimed in claim 9, wherein the gate isolation portion has a bottom surface at a level lower than that of each of the first and second source/drain portions and higher than that of each of the insulating portions, such that the first and second fin portions are connected with each other.

11. The method as claimed in claim 7, wherein
the first and second fin portions respectively have a first fin width and a second fin width in a third direction transverse to the first and second directions, at least one first effective channel layer having a first channel width in the third direction, each of the second effective channel layers having a second channel width in the third direction which is the same as the second fin width, the second channel width being greater than the first channel width.

12. The method as claimed in claim 7, further comprising, before forming the first and second devices, patterning the elongated fin such that the first and second fin portions are arranged discontinuously in the first direction.

13. A semiconductor structure, comprising:
a semiconductor substrate;
an elongated fin disposed on the semiconductor substrate, and having a first fin portion and a second fin portion which are displaced from each other in a first direction;
a first device disposed on the first fin portion and including
two first source/drain portions spaced apart from each other in the first direction,
a first channel portion including at least one first effective channel layer which extends between the two first source/drain portions, the first channel portion having a first width in a second direction transverse to the first direction, and
a first gate structure disposed around the at least one first effective channel layer such that two surfaces of the at least one first effective channel layer, which are opposite to each other in a third direction transverse to the first and second directions, are adjacent to the first gate structure, the first gate structure including a first gate feature, and a first gate dielectric layer disposed to separate the first gate feature from the at least one first effective channel layer; and
a second device disposed on the second fin portion and including
two second source/drain portions spaced apart from each other in the first direction,
a second channel portion including a plurality of second effective channel layers each of which extends between the two second source/drain portions, the second effective channel layers being separated from each other in the third direction, the second channel portion having a second width in the second direction, the second width being greater than the first width, and
a second gate structure disposed around the second effective channel layers such that two surfaces of each of the second effective channel layers, which are opposite to each other in the third direction, are adjacent to the second gate structure, the second gate structure including a second gate feature, and a second gate dielectric layer disposed to separate the second gate feature from the second effective channel layers, a number of the second effective channel layers being greater than a number of the at least one first effective channel layer.

14. The semiconductor structure as claimed in claim 13, wherein:
the first channel portion includes a plurality of first channel layers separated from each other in the third direction;
the second channel portion includes a plurality of second channel layers separated from each other in the third direction, a number of the first channel layers being equal to a number of the second channel layers;
the first device further includes two shielding elements, each of which is disposed between the first fin portion and a corresponding one of the first source/drain portions;
at least one of the first channel layers serves as the at least one first effective channel layer, a remainder of the first channel layers extending between the first shielding elements and serving as a first dummy channel feature, the first gate structure being disposed around the at least one first effective channel layer and the first dummy channel feature; and
all of the second channel layers serve as the second effective channel layers, respectively.

15. The semiconductor structure as claimed in claim 14, wherein each of the shielding elements is made of an undoped semiconductor material.

16. The semiconductor structure as claimed in claim 14, wherein each of the shielding elements is made of a dielectric material, and the second device further includes two dielectric elements, each of which is disposed between the second fin portion and a corresponding one of the second source/drain portions, the dielectric elements being made of a dielectric material the same as that of the shielding elements and being kept away from contact with the second effective channel layers.

17. The semiconductor structure as claimed in claim 13, wherein:
the first channel portion includes a plurality of first channel layers;
the second channel portion includes a plurality of second channel layers, a number of the first channel layers being equal to a number of the second channel layers;
the first device further includes two first shielding elements, each of which is disposed between the first fin portion and a corresponding one of the first source/drain portions;
the second device further includes two second shielding elements, each of which is disposed between the second fin portion and a corresponding one of the second source/drain portions;
at least one of the first channel layers serves as the at least one first effective channel layer, a remainder of the first channel layers extending between the first shielding elements and serving as a first dummy channel feature, the first gate structure being disposed around the at least one first effective channel layer and the first dummy channel feature; and
at least two of the second channel layers serve as the second effective channel layers, a remainder of the second channel layers extending between the second shielding elements and serving as a second dummy channel feature, the second gate structure being disposed around the second effective channel layers and the second dummy channel feature.

18. The semiconductor structure as claimed in claim 17, wherein each of the first and second shielding elements is made of an undoped semiconductor material or a dielectric material.

19. The semiconductor structure as claimed in claim 13, wherein:
the first channel portion includes a plurality of first channel layers each of which extends between the first source/drain portions;
the second channel portion includes a plurality of second channel layers each of which extends between the second source/drain portions, a number of the first channel layers being equal to a number of the second channel layers;
the first device further includes at least one sacrificial layer which at least shields a lower surface of a bottommost one of the first channel layers so as to permit at least an uppermost one of the first channel layers to serve as the at least one first effective channel layer; and
all of the second channel layers serve as the second effective channel features, respectively.

20. The semiconductor structure of claim 13, wherein:
the first channel portion includes a plurality of first channel layers each of which extends between the first source/drain portions;
the second channel portion includes a plurality of second channel layers each of which extends between the second source/drain portions, a number of the first channel layers being equal to a number of the second channel layers;
the first device further includes at least two first sacrificial layers which at least shield lower surfaces of two bottommost ones of the first channel layers, respectively, so as to permit at least an uppermost one of the first channel layers to serve as the at least one first effective channel layer; and
the second device further includes at least one second sacrificial layer which at least shields a lower surface of a bottommost one of the second channel layers so as to permit at least two uppermost ones of the second channel layers to serve as the second effective channel layers.
